(19) United States
(12) Patent Application Publication
(10) Pub. No.: US 2025/0046747 A1
(43) Pub. Date: Feb. 6, 2025

(54) SEMICONDUCTOR PACKAGE

(71) Applicant: SAMSUNG ELECTRONICS CO., LTD., Suwon-si (KR)

(72) Inventors: Junyun KWEON, Suwon-si (KR); Wooju KIM, Suwon-si (KR); Kangil YUN, Suwon-si (KR); Junho YOON, Suwon-si (KR); Dayoung CHO, Suwon-si (KR); Jinwook HONG, Suwon-si (KR)

(21) Appl. No.: 18/417,810

(22) Filed: Jan. 19, 2024

(30) Foreign Application Priority Data
Aug. 1, 2023 (KR) 10-2023-0100702

(51) Int. Cl. H01L 23/00; H01L 21/304; H01L 21/306; H01L 23/31; H01L 25/00; H01L 25/065; H01L 25/18

(52) U.S. Cl. CPC H01L 24/32; H01L 24/05; H01L 24/26; H01L 24/29; H01L 24/30; H01L 24/33; H01L 24/73; H01L 25/0657; H01L 25/18; H01L 25/50; H01L 21/304; H01L 21/30625; H01L 23/3128; H01L 24/06; H01L 24/27; H01L 24/83; H01L 24/92; H01L 2224/05554; H01L 2224/05567; H01L 2224/05624; H01L 2224/05647; H01L 2224/05666; H01L 2224/0603; H01L 2224/26122; H01L 2224/27002; H01L 2224/2741; H01L 2224/27452; H01L 2224/27515; H01L 2224/27616; H01L 2224/27622; H01L 2224/29011; H01L 2224/29186; H01L 2224/2919; H01L 2224/30181; H01L 2224/32145; H01L 2224/32225; H01L 2224/33181; H01L 2224/45144; H01L 2224/48091; H01L 2224/48145; H01L 2224/48227; H01L 2224/49112; H01L 2224/73215; H01L 2224/73265; H01L 2224/83896; H01L 2224/92147; H01L 2224/92247; H01L 2224/94; H01L 2225/06562; H01L 2924/0544; H01L 2924/059; H01L 2924/1436; H01L 2924/20104; H01L 2924/20105; H01L 2924/20106

(57) ABSTRACT

A semiconductor package includes a substrate, a first semiconductor chip on the substrate and including a first chip pad and a first upper insulating layer on sidewalls of the first chip pad, a first bonding wire on a top surface of the first chip pad and connected to the first chip pad, and a second semiconductor chip on a top surface of the first semiconductor chip and spaced apart from the first chip pad, wherein the second semiconductor chip includes a second semiconductor die and a second lower insulating layer on a bottom surface of the second semiconductor die, wherein the second lower insulating layer may be directly bonded to the first upper insulating layer by a chemical bond between the first upper insulating layer and the second lower insulating layer.

### CROSS-REFERENCE TO RELATED APPLICATION

This application is based on and claims priority under 35 U.S.C. § 119 to Korean Patent Application No. 10-2023-0100702, filed on Aug. 1, 2023, in the Korean Intellectual Property Office, the disclosure of which is incorporated by reference herein in its entirety.

### BACKGROUND

The inventive concept relates to a semiconductor package, and more particularly, to a semiconductor package including stacked semiconductor chips.

The semiconductor package is an implementation of an integrated circuit chip in a form suitable for use in electronic products. Typically, the semiconductor package is configured such that a semiconductor chip is mounted on a printed circuit board (PCB) and bonding wires or bumps are used to electrically connect the semiconductor chip to the printed circuit board. According to the miniaturization trend of semiconductor products, the size reduction of the semiconductor package is required. There is a need to reduce the package size while stacking a large number of semiconductor chips on one another to expand capacity and function of the package.

### SUMMARY

The inventive concept provides a miniaturized semiconductor package.

According to an aspect of the inventive concept, there is provided a semiconductor package including a substrate, a first semiconductor chip on the substrate and including a first chip pad and a first upper insulating layer on sidewalls of the first chip pad, a first bonding wire on a top surface of the first chip pad and connected to the first chip pad, and a second semiconductor chip on a top surface of the first semiconductor chip and spaced apart from the first chip pad, wherein the second semiconductor chip includes a second semiconductor die and a second lower insulating layer on a bottom surface of the second semiconductor die, wherein the second lower insulating layer may be directly bonded to the first upper insulating layer by a chemical bond between the first upper insulating layer and the second lower insulating layer.

According to another aspect of the inventive concept, there is provided a semiconductor package including a substrate, a first semiconductor die on the substrate and having a first pad region and a first mounting region, a first chip pad on a top surface of the first pad region of the first semiconductor die, a second semiconductor die on the first mounting region of the first semiconductor die and spaced apart from the first chip pad, and a first bonding insulating layer between the first and second semiconductor dies, wherein the first bonding insulating layer includes a first upper insulating layer on a top surface of the first semiconductor die and a second lower insulating layer on a bottom surface of the second semiconductor die, wherein the second lower insulating layer may be directly bonded to the first upper insulating layer without an interface therebetween.

According to another aspect of the inventive concept, there is provided a semiconductor package including a substrate, solder balls on a bottom surface of the substrate, a first semiconductor chip on a top surface of the substrate and including a first semiconductor die, first integrated circuits, a first wiring layer, a first redistribution pattern, a first chip pad, and a first upper insulating layer, a second semiconductor chip on the first semiconductor chip and spaced apart from the first chip pad, wherein the second semiconductor chip includes a second semiconductor die, second integrated circuits, a second wiring layer, a second redistribution pattern, a second chip pad, a second lower insulating layer, and a second upper insulating layer, a first bonding wire connected to the first chip pad, a second bonding wire connected to the second chip pad, and a molding layer on the substrate and surrounding the first semiconductor chip, the second semiconductor chip, the first bonding wire, and the second bonding wire, wherein the first semiconductor die may include a mounting region and a pad region, the first chip pad may be in the pad region of the first semiconductor die and laterally spaced apart from the mounting region, the second semiconductor chip may be in the mounting region of the first semiconductor die and laterally spaced apart from the pad region, the first upper insulating layer may be on a top surface of the mounting and the pad regions of the first semiconductor die, and may be on side walls of the first chip pad, a top surface of the first upper insulating layer may be at a higher level than a top surface of the first chip pad and a top surface of the first redistribution pattern, and the second lower insulating layer may be directly bonded to the first upper insulating layer.

### BRIEF DESCRIPTION OF THE DRAWINGS

Embodiments of the inventive concept will be more clearly understood from the following detailed description taken in conjunction with the accompanying drawings in which:

FIG. 1A is a cross-sectional view illustrating a semiconductor package according to embodiments;

FIG. 1B is an enlarged plan view of a portion of the first semiconductor chip;

FIG. 1C is an enlarged cross-sectional view for explaining bonding between the first semiconductor chip and a second semiconductor chip, which illustrates a region I of FIG. 1A and a cross-section taken along line A-B of FIG. 1B;

FIG. 1D is an enlarged cross-sectional view for explaining bonding between the second semiconductor chip and a third semiconductor chip, which illustrates a region II of FIG. 1A;

FIG. 1E is an enlarged cross-sectional view for explaining bonding between the third semiconductor chip and a fourth semiconductor chip, which illustrates a region III of FIG. 1A;

FIG. 2A is a cross-sectional view illustrating a semiconductor package according to embodiments;

FIG. 2B is an enlarged plan view illustrating a portion of a first semiconductor chip according to embodiments;

FIG. 2C is an enlarged cross-sectional view illustrating a region I of FIG. 2A and a cross-section taken along a line A-B of FIG. 2B;

FIG. 3A is a cross-sectional view for explaining a first semiconductor chip according to embodiments, which corresponds to an enlarged view of the region I of FIG. 1A;

FIG. 3B is a cross-sectional view for explaining a second semiconductor chip according to embodiments, which corresponds to an enlarged view of the region II of FIG. 1A;

FIG. 3C is a cross-sectional view for explaining a third semiconductor chip according to embodiments, which corresponds to an enlarged view of the region III of FIG. 1A;

FIGS. 4A to 4I are cross-sectional views for explaining a fabrication process of a semiconductor chip according to embodiments;

FIGS. 5A to 5D are cross-sectional views for explaining a fabrication process of a semiconductor package according to embodiments;

FIG. 6 is a cross-sectional view illustrating a semiconductor package according to embodiments; and

FIG. 7 is a cross-sectional view illustrating a semiconductor package according to embodiments.

### DETAILED DESCRIPTION OF THE EMBODIMENTS

Throughout this specification, the same reference numerals may refer to the same component. A semiconductor package and a manufacturing method thereof according to the inventive concept will be described below.

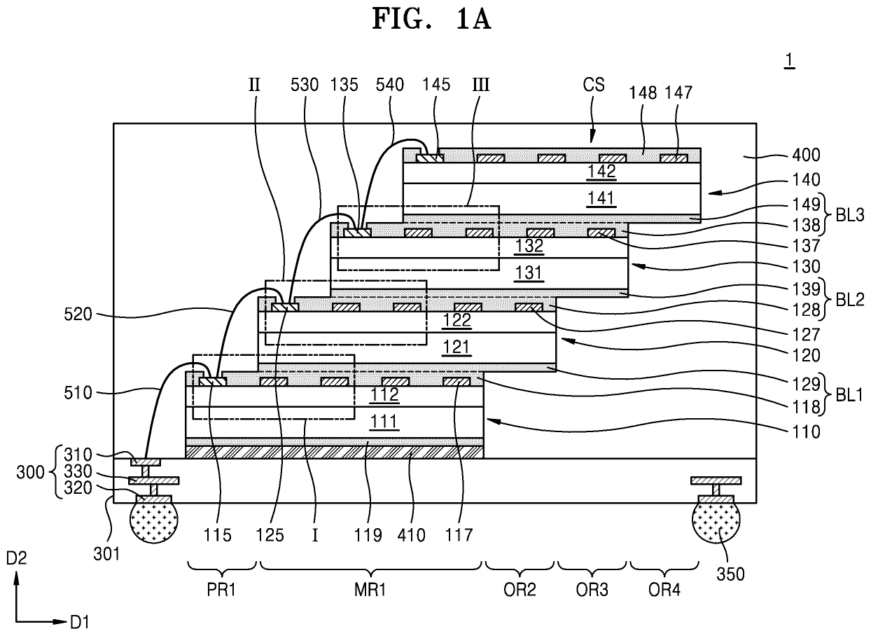

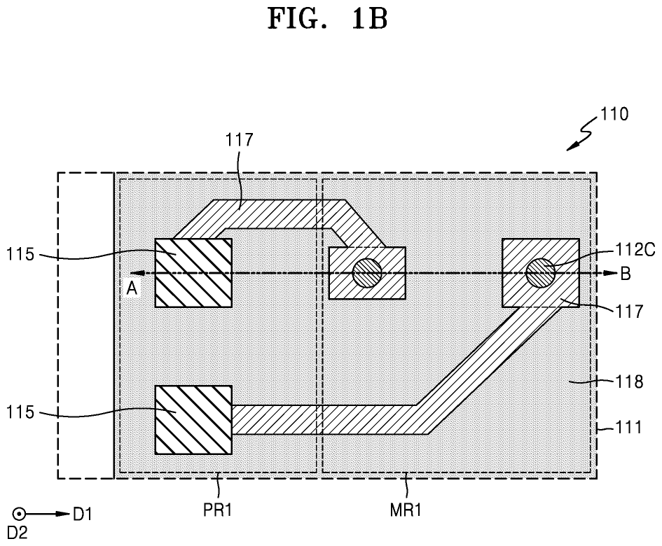

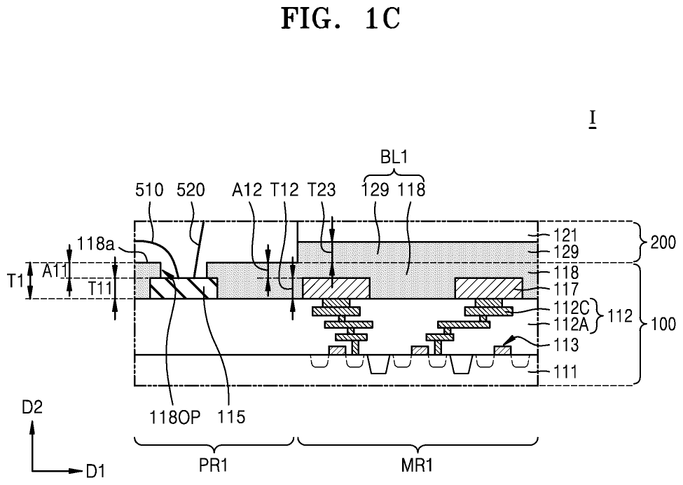

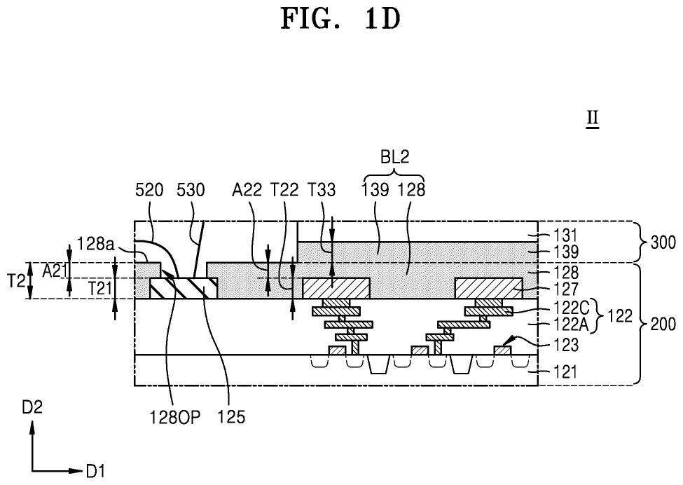

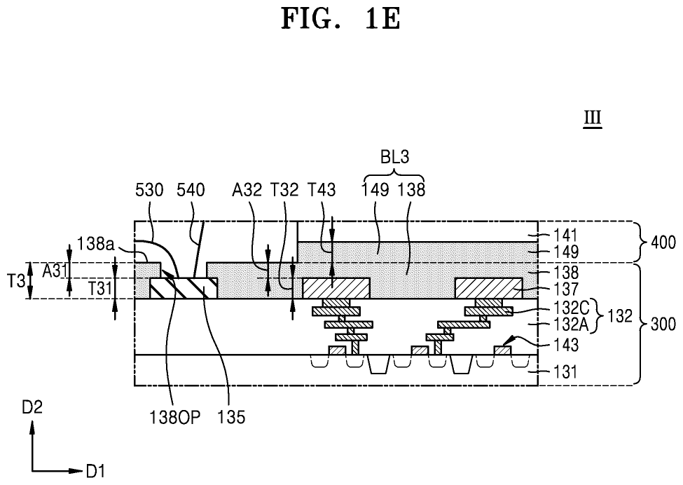

FIG. 1A is a cross-sectional view illustrating a semiconductor package according to embodiments.

Referring to FIG. 1A, a semiconductor package 1 may include a substrate 300, solder balls 350, a first semiconductor chip 110, a second semiconductor chip 120, a first bonding wire 510, a second bonding wire 520, and a molding layer 400. The semiconductor package 1 may further include a third semiconductor chip 130 and a third bonding wire 530. The semiconductor package 1 may further include a fourth semiconductor chip 140 and a fourth bonding wire 540. The first to fourth semiconductor chips 110, 120, 130, and 140 may constitute a chip stack CS.

The substrate 300 may include lower substrate pads 320, upper substrate pads 310, and conductive patterns 330. For example, the substrate 300 may include a printed circuit board (PCB). A first direction D1 may be parallel to the top surface of the substrate 300. A second direction D2 may be substantially perpendicular to the top surface of the substrate 300.

The lower substrate pads 320 may be provided on the bottom surface of the substrate 300. The conductive patterns 330 may be provided in the substrate 300 and may be connected to the lower substrate pads 320. The conductive patterns 330 may include vias and wires. When the two components are electrically joined/connected to each other, the two components are directly or indirectly joined/connected to each other through another conductive component.

The upper substrate pad 310 may be provided on the top surface of the substrate 300. The upper substrate pad 310 may be disposed adjacent to a first side surface 301 of the substrate 300 in a plan view. The first side surface 301 of the substrate 300 may face a direction opposite to the first direction D1. The upper substrate pad 310 may be electrically connected to at least one of the lower substrate pads 320 through the conductive patterns 330. The lower substrate pads 320, the conductive patterns 330, and the upper substrate pads 310 may include a metal such as aluminum, copper, tungsten, and/or titanium. To be electrically connected to the substrate 300 may mean to be electrically connected to the upper substrate pad 310. Although not shown, a plurality of upper substrate pads 310 may be provided to the substrate 300.

The solder balls 350 may be respectively provided on bottom surfaces of the lower substrate pads 320 and may be respectively connected to the lower substrate pads 320. The solder balls 350 may include a metal such as a solder material. The solder material may include, for example, tin (Sn), silver (Ag), zinc (Zn), and/or alloys thereof.

The first semiconductor chip 110 may be disposed on the top surface of the substrate 300. The first semiconductor chip 110 may include, for example, a memory chip such as dynamic random-access memory (DRAM) or a NAND. As another example, the first semiconductor chip 110 may be, for example, a logic chip or a buffer chip.

The first semiconductor chip 110 may include a first semiconductor die 111, a first wiring layer 112, a first chip pad 115, a first redistribution pattern 117, and a first upper insulating layer 118. The first semiconductor die 111 may include a semiconductor material. The semiconductor material may include, for example, silicon, germanium, or silicon-germanium, and may have a crystalline structure. The bottom surface of the first semiconductor die 111 may be a rear surface, and the top surface of the first semiconductor die 111 may be a front surface. The first semiconductor die 111 may have a first pad region PRI and a first mounting region MR1 in a plan view. The first pad region PRI of the first semiconductor die 111 may be adjacent to the first side surface 301 of the substrate 300 in a plan view. For example, the first pad region PRI of the first semiconductor die 111 may be provided between the first side surface 301 of the substrate 300 and the first mounting region MR1 of the first semiconductor die 111.

The first wiring layer 112 may be disposed on the top surface of the first semiconductor die 111. The first wiring layer 112 may include a front-end of line (FEOL) layer and a back-end of line (BEOL) layer.

The first chip pad 115 may be provided on the top surface of the first wiring layer 112. The first chip pad 115 may be provided on the first pad region PRI of the first semiconductor die 111 but may not be provided on the first mounting region MR1. The first chip pad 115 may include, for example, a metal such as aluminum, copper, and/or titanium.

The first redistribution pattern 117 is provided on the top surface of the first wiring layer 112 and may be disposed on one side of the first chip pad 115. In a plan view, the first chip pad 115 may be disposed between one side of the first semiconductor die 111 and the first redistribution pattern 117. One side surface of the first semiconductor die 111 may face a direction opposite to the first direction D1. The first redistribution pattern 117 may include a metal.

The first upper insulating layer 118 may be provided on the first wiring layer 112 and may cover the first redistribution pattern 117. The first upper insulating layer 118 may cover the sidewalls of the first chip pad 115 and expose the top surface of the first chip pad 115, as illustrated in FIG. 1A. The first upper insulating layer 118 may include an inorganic insulating material and/or an organic insulating material. The inorganic insulating material may include, for example, silicon. For example, the first upper insulating layer 118 may include a silicon-containing material such as silicon oxide (SiOx) and/or silicon carbide nitride (SiCxNy). For example, when the first upper insulating layer 118 includes a silicon-containing material, the first upper insulating layer 118 may further include at least one of carbon, nitrogen, and oxygen. The organic insulating material may include at least one of carbon, nitrogen, and oxygen. The organic insulating material may include a polymer.

The first bonding wire 510 may be provided on the first semiconductor chip 110. The first bonding wire 510 is provided on the top surface of the first chip pad 115, and may be connected to the upper substrate pad 310 and the first chip pad 115. Accordingly, the first semiconductor chip 110 may be electrically connected to an external device through the substrate 300 and the solder balls 350. The first bonding wire 510 may include a metal such as gold (Au) or a gold alloy.

The first semiconductor chip 110 may further include a first lower insulating layer 119. The first lower insulating layer 119 may include an inorganic insulation material and/or an organic insulation material as described in the example of the first upper insulating layer 118. Otherwise, the first semiconductor chip 110 may not include the first lower insulating layer 119.

The semiconductor package 1 may further include an adhesive layer 410. The adhesive layer 410 may be disposed between the substrate 300 and the first semiconductor chip 110. The first semiconductor chip 110 may be attached to the substrate 300 through the adhesive layer 410. The adhesive layer 410 may be a die attach film. The adhesive layer 410 may include, for example, an insulating polymer.

The second semiconductor chip 120 may be shifted in the first direction D1 from the first semiconductor chip 110, as illustrated in FIG. 1A. The second semiconductor chip 120 is provided on the top surface of the first mounting region MR1 of the first semiconductor die 111 and may be spaced apart from the first pad region PRI of the first semiconductor die 111 in a plan view. Accordingly, the first chip pad 115 may be exposed by the second semiconductor chip 120.

The second semiconductor chip 120 may be a semiconductor chip of the same type as the first semiconductor chip 110. For example, the second semiconductor chip 120 may be a memory chip such as DRAM or a NAND. The second semiconductor chip 120 may have substantially the same size as the first semiconductor chip 110. When the sizes, thicknesses, and levels of certain components are the same as each other, it may mean that an identity of the same error range may occur in the process.

The second semiconductor chip 120 may include a second semiconductor die 121, a second wiring layer 122, a second chip pad 125, a second redistribution pattern 127, a second upper insulating layer 128, and a second lower insulating layer 129. The second semiconductor die 121 may include a semiconductor material as described in the example of the first semiconductor die 111. Since the second semiconductor chip 120 is shifted from the first semiconductor chip 110, the second semiconductor die 121 may have a second overhang region OR2. In other words, the second semiconductor die 121 has a portion, referred to as the second overhang region OR2, that protrudes outward from the first semiconductor chip 110 so as to overhang the first semiconductor chip 110, as illustrated in FIG. 1A.

The second overhang region OR2 of the second semiconductor die 121 may be spaced apart from the first semiconductor chip 110 in a plan view. The bottom surface of the second semiconductor die 121 may be a rear surface, and the top surface of the second semiconductor die 121 may be a front surface.

The second chip pad 125 may be provided on the top surface of the second semiconductor die 121. The second chip pad 125 may be disposed adjacent to one side surface of the second semiconductor die 121 in a plan view. One side surface of the second semiconductor die 121 may face a direction opposite to the first direction D1. The second chip pad 125 may include, for example, a metal such as aluminum, copper, and/or titanium.

The second redistribution pattern 127 is provided on the top surface of the second semiconductor die 121 and may be disposed at one side of the second chip pad 125. In a plan view, the second chip pad 125 may be disposed between one side of the second semiconductor die 121 and the second redistribution pattern 127. The second redistribution pattern 127 may include a metal.

The second upper insulating layer 128 may be provided on the top surface of the second semiconductor die 121 and may cover the second redistribution pattern 127, as illustrated in FIG. 1A. The second upper insulating layer 128 may cover sidewalls of the second chip pad 125 and expose the top surface of the second chip pad 125, as illustrated in FIG. 1A. The second upper insulating layer 128 may include an inorganic insulating material and/or an organic insulating material. The inorganic insulating material and the organic insulating material are the same as those described in the example of the first upper insulating layer 118.

The second wiring layer 122 may be disposed between the second semiconductor die 121 and the second chip pad 125, between the second semiconductor die 121 and the second redistribution pattern 127, and between the second semiconductor die 121 and the third upper insulating layer 128.

The second bonding wire 520 may be provided on the top surface of the first chip pad 115. The second bonding wire 520 may be connected to the first chip pad 115 and the second chip pad 125. Accordingly, the second semiconductor chip 120 may be electrically connected to the substrate 300 via the first chip pad 115. For example, the second chip pad 125 may be electrically connected to the substrate 300 through a second bonding wire 520, a first chip pad 115, and a first bonding wire 510. The second bonding wire 520 may include a metal such as gold (Au) or a gold alloy. Otherwise, the second bonding wire 520 may connected to the second chip pad 125 and the upper substrate pad 310. In this case, the second semiconductor chip 120 may be electrically connected to the substrate 300 without passing through the first chip pad 115.

The second lower insulating layer 129 may be provided on the bottom surface of the second semiconductor die 121. The second lower insulating layer 129 may be in physical contact with the bottom surface of the second semiconductor die 121. The second lower insulating layer 129 on the bottom surface of the second overhang region OR2 of the second semiconductor die 121 may be spaced apart from the first semiconductor chip 110 in a plan view. For example, the second lower insulating layer 129 may include a first portion and a second portion. The first portion of the second lower insulating layer 129 may be disposed on the bottom surface of the second overhang region OR2 of the second semiconductor die 121. The bottom surface of the first portion of the second lower insulating layer 129 may be spaced apart from the first semiconductor chip 110. The second portion of the second lower insulating layer 129 may be disposed between the top surface of the first semiconductor die 111 and the bottom surface of the second semiconductor die 121. The second portion of the second lower insulating layer 129 may be integrally formed with the first portion. The second portion of the second lower insulating layer 129 may be bonded to the first upper insulating layer 118. According to embodiments, the first upper insulating layer 118 and the second lower insulating layer 129 may be directly connected by bonding to form a first bonding insulating layer BL1. The second semiconductor die 121 may be stably fixed to the first semiconductor die 111 by the first bonding insulating layer BL1. An adhesive layer such as a die attach film is omitted between the first semiconductor chip 110 and the second semiconductor chip 120 so that the height of the semiconductor package 1 may be reduced. Bonding of the first upper insulating layer 118 and the second lower insulating layer 129 will be described in more detail with reference to FIG. 1C. The second lower insulating layer 129 may include an inorganic insulating material or an organic insulating material.

The third semiconductor chip 130 may be arranged shifted in the first direction D1 from the second semiconductor chip 120, as illustrated in FIG. 1A. Therefore, the third semiconductor chip 130 may be spaced apart from the second chip pad 125. The third semiconductor chip 130 may be a semiconductor chip of the same type as the second semiconductor chip 120. The third semiconductor chip 130 may have substantially the same size as the second semiconductor chip 120.

The third semiconductor chip 130 may include a third semiconductor die 131, a third wiring layer 132, a third chip pad 135, a third redistribution pattern 137, a third upper insulating layer 138, and a third lower insulating layer 139. The third semiconductor die 131 may include a semiconductor material. Since the third semiconductor chip 130 is arranged shifted, the third semiconductor die 131 may have a third overhang region OR3. The third overhang region OR3 of the third semiconductor die 131 may be spaced apart from the second semiconductor chip 120 in a plan view. The top surface of the third semiconductor die 131 may be a front surface.

The third wiring layer 132 may be disposed on the top surface of the third semiconductor die 131. The third wiring layer 132 may include an FEOL layer and a BEOL layer.

The third chip pad 135 may be provided on the top surface of the third wiring layer 132. The third chip pad 135 may include, for example, a metal such as aluminum, copper, and/or titanium.

The third redistribution pattern 137 is provided on the top surface of the third wiring layer 132 and may be disposed at one side of the third chip pad 135. In a plan view, the third chip pad 135 may be disposed between one side of the third semiconductor die 131 and the third redistribution pattern 137. One side surface of the third semiconductor die 131 may face a direction opposite to the first direction D1. The third redistribution pattern 137 may include a metal.

The third upper insulating layer 138 may be provided on the top surface of the third wiring layer 132 and cover the third redistribution pattern 137, as illustrated in FIG. 1A. The third upper insulating layer 138 may cover the sidewalls of the third chip pad 135 and expose the top surface of the third chip pad 135, as illustrated in FIG. 1A. The third upper insulating layer 138 may include an inorganic insulating material or an organic insulating material.

A third bonding wire 530 may be provided on the top surface of the second chip pad 125 and the top surface of the third chip pad 135 to be connected to the second chip pad 125 and the third chip pad 135. Accordingly, the third semiconductor chip 130 may be electrically connected to the substrate 300 via the second chip pad 125 and the first chip pad 115. For example, the third chip pad 135 may be electrically connected to the substrate 300 through the third bonding wire 530, the second chip pad 125, the second bonding wire 520, the first chip pad 115, and the first bonding wire 510. Otherwise, the third bonding wire 530 may directly connected to the third chip pad 135 and the upper substrate pad 310. In this case, the third semiconductor chip 130 may be electrically connected to the substrate 300 without passing through the first chip pad 115 and the second chip pad 125. The third bonding wire 530 may include a metal such as gold (Au) or a gold alloy.

The third lower insulating layer 139 may be provided on the bottom surface of the third semiconductor diode 131. The third lower insulating layer 139 may be in direct contact with the bottom surface of the third semiconductor die 131. The third lower insulating layer 139 may include a first portion and a second portion. The first portion of the third lower insulating layer 139 may be disposed on the bottom surface of the third overhang region OR3 of the third semiconductor die 131. The bottom surface of the first portion of the third lower insulating layer 139 may be spaced apart from the second semiconductor chip 120. The second portion of the third lower insulating layer 139 may be disposed between the top surface of the second semiconductor die 121 and the bottom surface of the third semiconductor die 131. The second portion of the third lower insulating layer 139 may be integrally formed with the first portion. The second portion of the third lower insulating layer 139 may be in contact with the second upper insulating layer 128 and may be bonded to the second upper insulating layer 128. According to embodiments, the second upper insulating layer 128 and the third lower insulating layer 139 may be directly connected by bonding to form a second bonding insulating layer BL2. Bonding of the second upper insulating layer 128 and the third lower insulating layer 139 will be described later with reference to FIG. 1D. The third lower insulating layer 139 may include an inorganic insulating material or an organic insulating material.

The fourth semiconductor chip 140 may be arranged shifted in the first direction D1 from the third semiconductor chip 130. The fourth semiconductor chip 140 may be spaced apart from the third chip pad 135. The fourth semiconductor chip 140 may be a semiconductor chip of the same type as the third semiconductor chip 130. The fourth semiconductor chip 140 may have substantially the same size as the third semiconductor chip 130.

The fourth semiconductor chip 140 may include a fourth semiconductor die 141, a fourth wiring layer 142, a fourth chip pad 145, a fourth redistribution pattern 147, a fourth upper insulating layer 148, and a fourth lower insulating layer 149. The fourth semiconductor die 141 may include a semiconductor material. Since the fourth semiconductor chip 140 is arranged shifted, the fourth semiconductor die 141 may have a fourth overhang region OR4. The top surface of the fourth semiconductor die 141 may be a front surface.

The fourth wiring layer 142 may be disposed on the top surface of the fourth semiconductor die 141. The fourth chip pad 145 and the fourth redistribution pattern 147 may be disposed on the fourth wiring layer 142. The fourth chip pad 145 may include, for example, a metal such as aluminum, copper, and/or titanium. The fourth redistribution pattern 147 may be disposed on one side of the fourth chip pad 145. Although not shown, the fourth redistribution pattern 147 may be electrically coupled to the fourth chip pad 145.

The fourth upper insulating layer 148 may be disposed on the fourth wiring layer 142 and cover the sidewalls and the top surface of the fourth redistribution pattern 147, as illustrated in FIG. 1A. The fourth upper insulating layer 148 may cover a sidewall of the fourth chip pad 145 and expose the top surface of the fourth chip pad 145, as illustrated in FIG. 1A. The fourth upper insulating layer 148 may include an inorganic insulating material and/or an organic insulating material.

A fourth bonding wire 540 is provided on the top surface of the third chip pad 135 and on the top surface of the fourth chip pad 145, to be connected to the third chip pad 135 and the fourth chip pad 145. Accordingly, the fourth semiconductor chip 140 may be electrically connected to the substrate 300 via the first to third chip pads 115, 125, and 135. The fourth bonding wire 540 may include a metal such as gold (Au) or a gold alloy.

The fourth lower insulating layer 149 may be provided on the bottom surface of the fourth semiconductor die 141. The fourth lower insulating layer 149 may be in physical contact with the bottom surface of the fourth semiconductor die 141. The fourth lower insulating layer 149 may include a first portion and a second portion. The first portion of the fourth lower insulating layer 149 may be disposed in the fourth overhang region OR4 of the fourth semiconductor die 141. The bottom surface of the first portion of the fourth lower insulating layer 149 may be spaced apart from the third semiconductor chip 130. The second portion of the fourth lower insulating layer 149 may be disposed between the top surface of the third semiconductor die 131 and the bottom surface of the fourth semiconductor die 141. The second portion of the fourth lower insulating layer 149 may be integrally formed with the first portion. The second portion of the fourth lower insulating layer 149 may be in contact with the third upper insulating layer 138 and may be bonded to the third upper insulating layer 138. According to embodiments, the third upper insulating layer 138 and the fourth lower insulating layer 149 may be directly bonded to form a third bonding insulating layer BL3. Bonding of the third upper insulating layer 138 and the fourth lower insulating layer 149 will be described with reference to FIG. 1E. The fourth lower insulating layer 149 may include an inorganic insulating material or an organic insulating material.

For example, a material of the first upper insulating layer 118 may be substantially the same as a material of the second upper insulating layer 128, a material of the third upper insulating layer 138, and a material of the fourth upper insulating layer 148. A material of the second lower insulating layer 129 may be substantially the same as a material of the first lower insulating layer 119, a material of the third lower insulating layer 139, and a material of the fourth lower insulating layer 149. A material of the first upper insulating layer 118 may be substantially the same as a material of the second upper insulating layer 128, a material of the third upper insulating layer 138, a material of the fourth upper insulating layer 148, a material of the first lower insulating layer 119, a material of the second lower insulating layer 129, a material of the third lower insulating layer 139, and a material of the fourth lower insulating layer 149. However, the embodiments are not limited thereto.

The molding layer 400 may be disposed on the substrate 300 to cover (i.e., encapsulate or surround) the first to fourth semiconductor chips 110, 120, 130, and 140 and the first to fourth bonding wires 510, 520, 530, and 540. The molding layer 400 may further cover bottom surfaces of the first portions of the second to fourth lower insulating layers 129, 139, and 149. The molding layer 400 may include an insulating polymer such as an epoxy-based molding compound. The molding layer 400 may prevent external impurities from penetrating the first to fourth semiconductor chips 110, 120, 130, and 140. Hereinafter, the bonding between the first upper insulating layer 118 and the second lower insulating layer 129 will be described in more detail.

FIG. 1B is an enlarged plan view of a portion of the first semiconductor chip, which is for explaining the connection between the first chip pad and the first redistribution pattern. FIG. 1C is an enlarged cross-sectional view for explaining bonding between the first semiconductor chip and a second semiconductor chip, which illustrates a region I of FIG. 1A and a cross-section taken along line A-B of FIG. 1B.

Referring to FIGS. 1B and 1C together with FIG. 1A, the first semiconductor chip 110 may further include first integrated circuits 113 of FIG. 1C. The first integrated circuits 113 may be provided on the top surface of the first semiconductor die 111. The first integrated circuits 113 may include, for example, transistors. The first integrated circuits 113 may form memory circuits but are not limited thereto.

The first wiring layer 112 may include a first insulating layer 112A and first wiring structures 112C. The first insulating layer 112A may be provided on the top surface of the first semiconductor die 111 and may cover the first integrated circuits 113. The first insulating layer 112A may be a multilayer. The first insulating layer 112A may include a silicon-containing insulating material. The silicon-containing insulating material may include, for example, silicon oxide, silicon nitride, silicon oxynitride, silicon carbide, silicon carbonitride, and/or tetraethyl orthosilicate. The first wiring structures 112C may be provided in the first insulating layer 112A. The first wiring structures 112C may be electrically connected to the first integrated circuits 113. The fact that a component is electrically connected to a semiconductor chip may mean that the component is electrically connected to integrated circuits through chip pads of the semiconductor chip. Each of the first wiring structures 112C may include first wirings and first vias connected to the first wirings. The first vias may be provided between the first wirings. The first wirings and the first vias may include a metal material.

The first chip pad 115 may be disposed on the top surface of the first insulating layer 112A. The first chip pad 115 may be spaced apart from the top surfaces of the first wiring structures 112C.

The first redistribution pattern 117 may be provided on the top surface of the first wiring layer 112. As shown in FIG. 1B, the first redistribution pattern 117 may be provided on the first pad region PRI and the first mounting region MR1 of the first semiconductor die 111. The first chip pad 115 may be electrically connected to the first redistribution pattern 117. As illustrated in FIG. 1C, the first redistribution pattern 117 may be electrically connected to at least one of the first wiring structures 112C. Accordingly, the first chip pad 115 may be electrically connected to the first integrated circuits 113 through the first redistribution pattern 117 and the at least one first wiring structure 112C. Since the first redistribution pattern 117 is provided, the arrangement of the first chip pad 115 may not be limited to the arrangement of the first integrated circuits 113 and the first wiring structures 112C. For example, the first chip pad 115 may be disposed on the first pad region PRI of the first semiconductor die 111 but may not be disposed on the first mounting region MR1.

The first redistribution pattern 117 may include the same metal material as the first chip pad 115. For example, the thickness T12 of the first redistribution pattern 117 may be about 95% to about 105% of the thickness T11 of the first chip pad 115. A plurality of first redistribution patterns 117 may be provided. In this case, the thickness of any one of the first redistribution patterns 117 may be about 95% to about 105% of the thickness of the other one of the first redistribution patterns 117. Each of the first redistribution patterns 117 may be formed by a single process with the first chip pad 115. Hereinafter, a single first redistribution pattern 117 will be described.

The first upper insulating layer 18 may be provided on the first insulating layer 112A. The first upper insulating layer 118 may cover sidewalls and the top surface of the first redistribution pattern 117, as illustrated in FIG. 1B. The first upper insulating layer 118 may cover the sidewalls of the first chip pad 115, as illustrated in FIG. 1B. The first upper insulating layer 118 may have a first pad opening 118OP, and the first pad opening 118OP may expose a center region of the top surface of the first chip pad 115. The first upper insulating layer 118 may further cover an edge region of the top surface of the first chip pad 115, as illustrated in FIG. 1B, but is not limited thereto. The top surface 118a of the first upper insulating layer 118 may be provided at a higher level than the top surface of the first chip pad 115.

The first upper insulating layer 118 may be an uppermost layer of the first semiconductor chip 110. For example, the top surface of the first semiconductor chip 110 may include the top surface 118a of the first upper insulating layer 118. The first semiconductor chip 110 may not include a separate organic protection layer on the top surface of the first upper insulating layer 118. Accordingly, the thickness of the first semiconductor chip 110 may be reduced.

According to embodiments, the top surface 118a of the first upper insulating layer 118 may be relatively flat. For example, a level difference between an uppermost portion and a lowermost portion of the top surface 118a of the first upper insulating layer 118 may be equal to or less than about 50 Å or less. In the present specification, the level of any component may mean a vertical level measured in a vertical direction. The vertical direction may be parallel to the second direction D2.

The first upper insulating layer 118 may have a first thickness T1. The first thickness T1 may correspond to a level difference between the top surface 118a of the first upper insulating layer 118 and the top surface of the first insulating layer 112A. The first thickness T1 may be about 1 μm to about 10 μm. Since the first thickness T1 is greater than or equal to about 1 μm, the top surface 118a of the first upper insulating layer 128 may be flat. Since the first thickness T1 is about 10 μm or less, the thickness of the second semiconductor chip 120 may be reduced.

A level difference A11 between the top surface 118a of the first upper insulating layer 118 and the top surface of the first chip pad 115 may be about 0.1 μm to about 2 μm. A level difference A12 between the top surface 118a of the first upper insulating layer 118 and the top surface of the first redistribution pattern 117 may be about 0.1 μm to about 2 μm. The level difference A12 between the top surface 118a of the first upper insulating layer 118 and the top surface of the first redistribution pattern 117 may correspond to the thickness of the first upper insulating layer 118 on the top surface of the first redistribution pattern 117.

A second lower insulating layer 129 may be disposed on the top surface 118a of a portion of the first upper insulating layer 118. The second lower insulating layer 129 may expose the top surface 118a of another portion of the first upper insulating layer 118. The first bonding insulating layer BL1 may include a first upper insulating layer 118 and a second lower insulating layer 129. The second lower insulating layer 129 may be connected to the first upper insulating layer 118 by direct bonding. For example, the top surface 118a of the first upper insulating layer 118 and the bottom surface 129 of the second lower insulating layer 129 are in direct contact with each other, and a chemical bond, such as a covalent bond, may be formed between the first upper insulating layer 118 and the second lower insulating layer 129. The second lower insulating layer 129 may be firmly fixed to the first upper insulating layer 118 by a chemical bond. The first upper insulating layer 118 and the second lower insulating layer 129 are connected without a boundary surface, and the interface between the top surface 118a of the first upper insulating layer 118 and the bottom surface 129 of the second lower insulating layer 129 may be indistinguishable. In FIGS. 1A and 1C, the interface between the first upper insulating layer 118 and the second lower insulating layer 129 may be a virtual interface but is not limited thereto.

When the first upper insulating layer 118 and the second lower insulating layer 129 include silicon oxide, the bonding between the first upper insulating layer 118 and the second lower insulating layer 129 may be oxide-to-oxide bonding. When the first upper insulating layer 118 and the second lower insulating layer 129 include a polymer, the bonding between the first upper insulating layer 118 and the second lower insulating layer 129 may be polymer-to-polymer bonding. For example, the second lower insulating layer 129 may include the same material as the first upper insulating layer 118.

When the top surface 118a of the first upper insulating layer 118 has a relatively large undulation, a void may be formed between the top surface 118a of the first upper insulating layer 118 and the bottom surface of the second lower insulating layer 129. In this case, it may be difficult to form a good direct bonding between the first upper insulating layer 118 and the second lower insulating layer 129. According to embodiments, since a level difference between an uppermost portion and a lowermost portion of the top surface 118a of the first upper insulating layer 118 is less than or equal to about 50 Å, a good direct bonding may be formed between the second lower insulating layer 129 and the top surface 118a of the first upper insulating layer 118.

When the level difference A12 between the top surface 118a of the first upper insulating layer 118 and the top surface of the first redistribution pattern 117 is too small (e.g., less than about 0.1 μm), it may be difficult for the first upper insulating layer 118 to be well bonded to the second lower insulating layer 129. According to embodiments, since the level difference A12 between the top surface 118a of the first upper insulating layer 118 and the top surface of the first redistribution pattern 117 is about 0.1 μm or more, the first upper insulating layer 118 may be well bonded to the second lower insulating layer 129. Since the level difference A12 between the top surface 118a of the first upper insulating layer 118 and the top surface of the first redistribution pattern 117 is less than about 2 μm, a stable bonding may be formed between the first upper insulating layer 118 and the second lower insulating layer 129. Accordingly, the second semiconductor die 121 may be more firmly bonded to the first semiconductor die 111 via the first bonding insulating layer BL1. Since a separate adhesive layer is not provided between the first semiconductor chip 110 and the second semiconductor chip 120, the height of the semiconductor package 1 may be reduced.

For example, the thickness T23 of the second lower insulating layer 129 may be less than the first thickness T1 of FIG. 1C The thickness T23 of the second lower insulating layer 129 may be less than the second thickness T2 of FIG. 1D and the third thickness T3 of FIG. 1E, which will be discussed later. Accordingly, the height of the semiconductor package 1 may be reduced. The thickness T23 of the second lower insulating layer 129 may be, for example, about 1 μm to about 10 μm.

FIG. 1D is an enlarged cross-sectional view for explaining bonding between the second semiconductor chip and a third semiconductor chip, which illustrates a region II of FIG. 1A.

Referring to FIG. 1D together with FIG. 1A, the second semiconductor chip 120 may further include second integrated circuits 123. The second integrated circuits 123 may be provided on the top surface of the second semiconductor die 121. The second integrated circuits 123 may include, for example, transistors. The second integrated circuits 123 may form memory circuits.

The second wiring layer 122 may include a second insulating layer 122A and second wiring structures 122C. The second insulating layer 122A may be provided on the top surface of the second semiconductor die 121 and may cover the second integrated circuits 123. The second insulating layer 122A may be a multilayer. The second insulating layer 122A may include a silicon-containing insulating material as described in the example of the first insulating layer 112A. The second wiring structures 122C are provided within the second insulating layer 122A and may be electrically connected to the second integrated circuits 123. Each of the second wiring structures 122C may include second wirings and second vias connected to the second wirings. The second wiring structures 122C may include a metal material.

The second chip pad 125 may be disposed on the top surface of the second insulating layer 122A. The second chip pad 125 may be spaced apart from the top surfaces of the second wiring structures 122C.

The second redistribution pattern 127 may be provided on the top surface of the second wiring layer 122. At least a portion of the second redistribution pattern 127 may vertically overlap the third semiconductor chip 130. The arrangement relationships and connection relationships of the second chip pad 125 and the second redistribution pattern 127 may be the same as or similar to those described in the example of the first chip pad 115 and the first redistribution pattern 117. For example, as described in the example connection of the first chip pad 115 and the first redistribution pattern 117 in FIG. 1B, the second chip pad 125 may be electrically connected with the second redistribution pattern 127. The second redistribution pattern 127 may be electrically connected to at least one of the second wiring structures 122C. Accordingly, the second chip pad 125 may be electrically connected to the second integrated circuits 123 via the second redistribution pattern 127 and the at least one second wiring structure 122C. Since the second redistribution pattern 127 is provided, the second chip pad 125 may be disposed in any desired region without being limited to the arrangement of the second integrated circuits 123 and the second wiring structures 122C. For example, the second chip pad 125 may be disposed adjacent to one side of the second semiconductor die 121 in a plan view and spaced apart from the third semiconductor chip 130.

The second redistribution pattern 127 may include the same metallic material as the second chip pad 125. The thickness T22 of the second redistribution pattern 127 may be about 95% to about 105% of the thickness T21 of the second chip pad 125. A plurality of second redistribution patterns 127 may be provided. In this case, the thickness of any one of the second redistribution patterns 127 may be about 95% to about 105% of the thickness of the other one of the second redistribution patterns 127. The second redistribution patterns 127 may be formed by a single process with the second chip pad 125. Hereinafter, a single second redistribution pattern 127 will be described.

The second upper insulating layer 128 may be provided on the second insulating layer 122A. The second upper insulating layer 128 may cover sidewalls and the top surface of the second redistribution pattern 127, as illustrated in FIG. 1D. The second upper insulating layer 128 may cover sidewalls of the second chip pad 125, as illustrated in FIG. 1D. The second upper insulating layer 128 may have a second pad opening 128OP, and the second pad opening 128OP may expose a center region of the top surface of the second chip pad 125, as illustrated in FIG. 1D. The second upper insulating layer 128 may further cover an edge region of the top surface of the second chip pad 125, as illustrated in FIG. 1D. The top surface 128a of the second upper insulating layer 128 may be provided at a higher level than the top surface of the second chip pad 125.

The second upper insulating layer 128 may be an uppermost layer of the second semiconductor chip 120. For example, the top surface of the second semiconductor chip 120 may include the top surface 128a of the second upper insulating layer 128. The second semiconductor chip 120 may not include a separate organic protection layer on the second upper insulating layer 128. Accordingly, the thickness of the second semiconductor chip 120 may be reduced.

The second upper insulating layer 128 may have a second thickness T2. The second thickness T2 may correspond to a level difference between the top surface 128a of the second upper insulating layer 128 and the top surface of the second insulating layer 122A. The second thickness T2 may be about 1 μm to about 10 μm. Since the second thickness T2 is greater than or equal to about 1 μm, the top surface 128a of the second upper insulating layer 128 may be flat. Since the second thickness T2 is about 10 μm or less, the thickness of the second semiconductor chip 120 may be reduced. The second thickness T2 may be substantially the same as the first thickness T1 of FIG. 1C. For example, the second thickness T2 may be greater than the thickness T23 of the second lower insulating layer 129 of FIG. 1C.

A level difference A21 between the top surface 128a of the second upper insulating layer 128 and the top surface of the second chip pad 125 may be about 0.1 μm to about 2 μm. A level difference A22 between the top surface 128a of the second upper insulating layer 128 and the top surface of the second redistribution pattern 127 may be about 0.1 μm to about 2 μm. The level difference A22 between the top surface 128a of the second upper insulating layer 128 and the top surface of the second redistribution pattern 127 may correspond to the thickness of the second upper insulating layer 128 on the top surface of the second redistribution pattern 127.

A third lower insulating layer 139 may be disposed on the top surface 128a of a portion of the second upper insulating layer 128. The third lower insulating layer 139 may be spaced apart from the top surface 128a of another portion of the second upper insulating layer 128. The second bonding insulating layer BL2 may include the second upper insulating layer 128 and the third lower insulating layer 139. The third lower insulating layer 139 may be connected to the second upper insulating layer 128 by direct bonding. For example, the top surface 128a of the second upper insulating layer 128 and the bottom surface 139 of the third lower insulating layer 139 are in direct contact with each other, and a chemical bond, such as a covalent bond, may be formed between the second upper insulating layer 128 and the third lower insulating layer 139. The second upper insulating layer 128 and the third lower insulating layer 139 are connected to each other without a boundary surface, and the interface between the top surface 128a of the second upper insulating layer 128 and the bottom surface 139 of the third lower insulating layer 139 may be indistinguishable. In FIGS. 1A and 1D, an interface between the second upper insulating layer 128 and the third lower insulating layer 139 may be a virtual interface.

When the second upper insulating layer 128 and the third lower insulating layer 139 include silicon oxide, the bonding between the second upper insulating layer 128 and the third lower insulating layer 139 may be oxide-to-oxide bonding. When the second upper insulating layer 128 and the third lower insulating layer 139 include a polymer, the bonding between the second upper insulating layer 128 and the third lower insulating layer 139 may be polymer-to-polymer bonding. For example, the third lower insulating layer 139 may include the same material as the second upper insulating layer 128.

According to embodiments, the top surface 128a of the second upper insulating layer 128 may be relatively flat. For example, a level difference between an uppermost portion and a lowermost portion of the top surface 128a of the second upper insulating layer 128 may be equal to or less than about 50 Å or less. Accordingly, a void may be prevented from being formed between the top surface 128a of the second upper insulating layer 128 and the bottom surface of the third lower insulating layer 139. A good direct bonding may be formed between the second lower insulating layer 129 and the top surface 118a of the first upper insulating layer 118.

According to embodiments, since the level difference A22 between the top surface 128a of the second upper insulating layer 128 and the top surface of the second redistribution pattern 127 is greater than or equal to about 0.1 μm, the second upper insulating layer 128 may be bonded to the third lower insulating layer 139 with a better condition. Since the level difference A22 between the top surface 128a of the second upper insulating layer 128 and the top surface of the second redistribution pattern 127 is less than or equal to about 2 μm, a stable bonding may be formed between the second upper insulating layer 128 and the third lower insulating layer 139. Accordingly, the third semiconductor die 131 may be more firmly bonded to the second semiconductor die 121 via the second bonding insulating layer BL2.

For example, the thickness T33 of the third lower insulating layer 139 may be less than the second thickness T2 of FIG. 1D. The thickness T33 of the third lower insulating layer 139 may be less than the first thickness T1 of FIG. 1C and the third thickness T3 of FIG. 1E, which will be discussed later. Accordingly, the thickness of the third semiconductor chip 130 may be reduced. The thickness T33 of the third lower insulating layer 139 may be, for example, about 1 μm to about 10 μm.

FIG. 1E is an enlarged cross-sectional view for explaining bonding between the third semiconductor chip and a fourth semiconductor chip, which illustrates a region III of FIG. 1A.

Referring to FIG. 1E in conjunction with FIG. 1A, the third semiconductor chip 130 may further include third integrated circuits 143. The third integrated circuits 143 may be provided on the top surface of the third semiconductor die 131. The third integrated circuits 143 may include, for example, transistors. The third integrated circuits 143 may form memory circuits.

The third wiring layer 132 may include a third insulating layer 132A and third wiring structures 132C. The third insulating layer 132A may be provided on the top surface of the third semiconductor die 131 and may cover the third integrated circuits 143. The third insulating layer 132A may be a multilayer. The third insulating layer 132A may include a silicon-containing insulating material. The third wiring structures 132C may be provided in the third insulating layer 132A. The third wiring structures 132C may be electrically connected to the third integrated circuit 143. The third wiring structures 132C may include a metal material.

The third chip pad 135 may be disposed on the top surface of the third insulating layer 132A. The third chip pad 135 may be spaced apart from the third wiring structures 132C.

The third redistribution pattern 137 may be provided on the top surface of the third wiring layer 132. At least a portion of the third redistribution pattern 137 may vertically overlap the fourth semiconductor chip 140. The arrangement relationships and connection relationships of the third chip pad 135 and the third redistribution pattern 137 may be the same as or similar to those described in the example of the first chip pad 115 and the first redistribution pattern 117. As described in the example connection of the first chip pad 115 and the first redistribution pattern 117 in FIG. 1B, the third chip pad 135 may be electrically connected with the third redistribution pattern 137. The third redistribution pattern 137 may be electrically connected to at least one of the third wiring structures 132C. Accordingly, the third chip pad 135 may be electrically connected to the third integrated circuits 143 via the third redistribution pattern 137 and the at least one third wiring structure 132C. Since the third redistribution pattern 137 is provided, the third chip pad 135 may be disposed in any desired region, without being limited to the arrangement of the third integrated circuits 143 and the third wiring structures 132C. For example, the third chip pad 135 may be disposed adjacent to one side of the third semiconductor die 131 in a plan view and spaced apart from the fourth semiconductor chip 140.

The third redistribution pattern 137 may include the same metallic material as the third chip pad 135. The thickness T32 of the third redistribution pattern 137 may be about 95% to about 105% of the thickness T31 of the third chip pad 135. A plurality of third redistribution patterns 137 may be provided. In this case, the thickness of any one of the third redistribution patterns 137 may be from about 95% to about 105% of the thickness of the other one of the third redistribution patterns 137. The third redistribution patterns 137 may be formed by a single process with the third chip pad 135. Hereinafter, a single third redistribution pattern 137 will be described.

The third upper insulating layer 138 may be provided on the third insulating layer 132A. The third upper insulating layer 138 may cover sidewalls and the top surface of the third redistribution pattern 137, as illustrated in FIG. 1E. The third upper insulating layer 138 may cover the sidewalls of the third chip pad 135, as illustrated in FIG. 1E. The third upper insulating layer 138 has a third pad opening 138OP, and the third pad opening 138OP may expose a center region of the top surface of the third chip pad 135, as illustrated in FIG. 1E. The third upper insulating layer 138 may further cover an edge region of the top surface of the third chip pad 135, as illustrated in FIG. 1E. The top surface 138a of the third upper insulating layer 138 may be provided at a higher level than the top surface of the third chip pad 135.

The third upper insulating layer 138 may be an uppermost layer of the third semiconductor chip 130. For example, the top surface of the third semiconductor chip 130 may include the top surface 138a of the third upper insulating layer 138. The third semiconductor chip 130 may not include a separate organic protection layer on the third upper insulating layer 138. Accordingly, the thickness of the third semiconductor chip 130 may be reduced.

A level difference A31 between the top surface 138a of the third upper insulating layer 138 and the top surface of the third chip pad 135 may be about 0.1 μm to about 2 μm. A level difference A32 between the top surface 138a of the third upper insulating layer 138 and the top surface of the third redistribution pattern 137 may be about 0.1 μm to about 2 μm. The level difference A32 between the top surface 138a of the third upper insulating layer 138 and the top surface of the third redistribution pattern 137 may correspond to the thickness of the third upper insulating layer 138 on the top surface of the third redistribution pattern 137.

The third upper insulating layer 138 may have a third thickness T3. The third thickness T3 may correspond to a level difference between the top surface 138a of the third upper insulating layer 138 and the top surface of the third insulating layer 132A. The third thickness T3 may be about 1 μm to about 10 μm. Since the third thickness T3 is greater than or equal to about 1 μm, the top surface 138a of the third upper insulating layer 138 may be flat. Since the third thickness T3 is about 10 μm or less, the thickness of the third semiconductor chip 130 may be reduced. The third thickness T3 may be substantially the same as the first thickness T1 of FIG. 1C and the second thickness T2 of FIG. 1D.

A fourth lower insulating layer 149 may be disposed on the top surface 138a of a portion of the third upper insulating layer 138. The fourth lower insulating layer 149 may be spaced apart from the top surface 138a of the other portion of the third upper insulating layer 138. The third bonding insulating layer BL3 may include the third upper insulating layer 138 and the fourth lower insulating layer 149. The fourth lower insulating layer 149 may be connected to the third upper insulating layer 138 by direct bonding. For example, the top surface 138a of the third upper insulating layer 138 and the bottom surface of the fourth lower insulating layer 149 are in direct contact with each other, and a chemical bond, such as a covalent bond, may be formed between the third upper insulating layer 138 and the fourth lower insulating layer 149. Since the third upper insulating layer 138 and the fourth lower insulating layer 149 are connected without a boundary surface, an interface between the top surface 138a of the third upper insulating layer 138 and the bottom surface of the fourth lower insulating layer 149 may be indistinguishable. In FIGS. 1A and 1E, the interface between the third upper insulating layer 138 and the fourth lower insulating layer 149 may be a virtual interface but is not limited thereto.

When the third upper insulating layer 138 and the fourth lower insulating layer 149 include silicon oxide, the bonding between the third upper insulating layer 138 and the fourth lower insulating layer 149 may be oxide-to-oxide bonding. When the third upper insulating layer 138 and the fourth lower insulating layer 149 include a polymer, the bonding between the third upper insulating layer 138 and the fourth lower insulating layer 149 may be polymer-to-polymer bonding. For example, the fourth lower insulating layer 149 may include the same material as the third upper insulating layer 138.

According to embodiments, the top surface 138a of the third upper insulating layer 138 may be relatively flat. For example, a level difference between an uppermost portion and a lowermost portion of the top surface 138a of the third upper insulating layer 138 may be about 50 Å or less. Accordingly, a void may be prevented from being formed between the top surface 138a of the third upper insulating layer 138 and the bottom surface of the fourth lower insulating layer 149. The fourth lower insulating layer 149 may be well directly bonded to the top surface 138a of the third upper insulating layer 138.

According to embodiments, since the level difference A32 between the top surface 138a of the third upper insulating layer 138 and the top surface of the third redistribution pattern 137 is greater than or equal to about 0.1 μm, the third upper insulating layer 138 may be well bonded to the fourth lower insulating layer 149. Since the level difference A32 between the top surface 138a of the third upper insulating layer 138 and the top surface of the third redistribution pattern 137 is less than or equal to about 2 μm, a stable bonding may be formed between the third upper insulating layer 138 and the fourth lower insulating layer 149. Accordingly, the fourth semiconductor die 141 may be more firmly bonded to the third semiconductor die 131 via the third bonding insulating layer BL3.

For example, the thickness T43 of the fourth lower insulating layer 149 may be less than the third thickness T3 of FIG. 1E. The thickness T43 of the fourth lower insulating layer 149 may be less than the first thickness T1 of FIG. 1C and the second thickness T2 of FIG. 1D. Accordingly, the thickness of the fourth semiconductor chip 140 may be reduced. The thickness T43 of the fourth lower insulating layer 149 may be, for example, about 1 μm to about 10 μm.

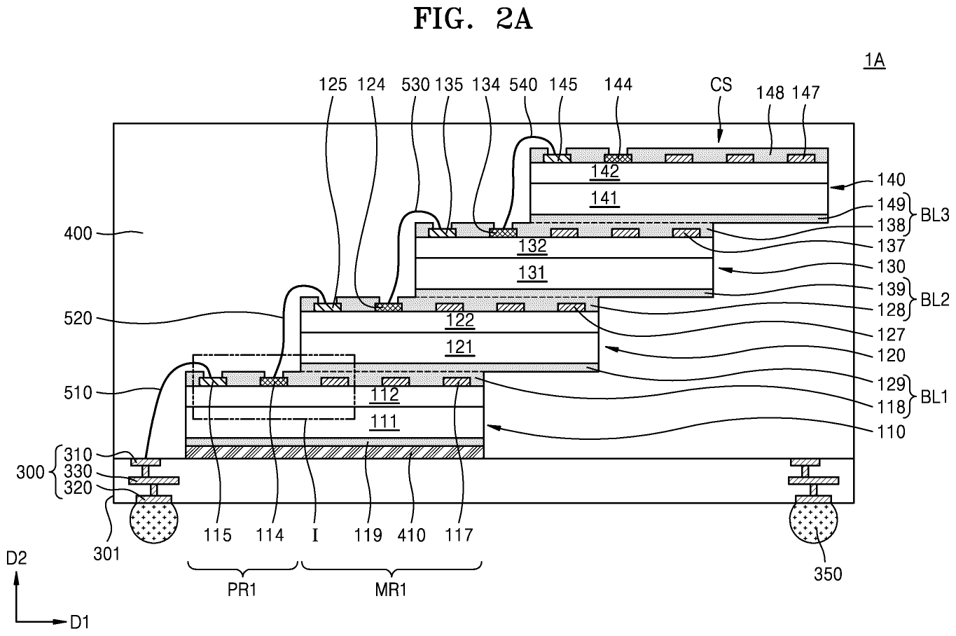

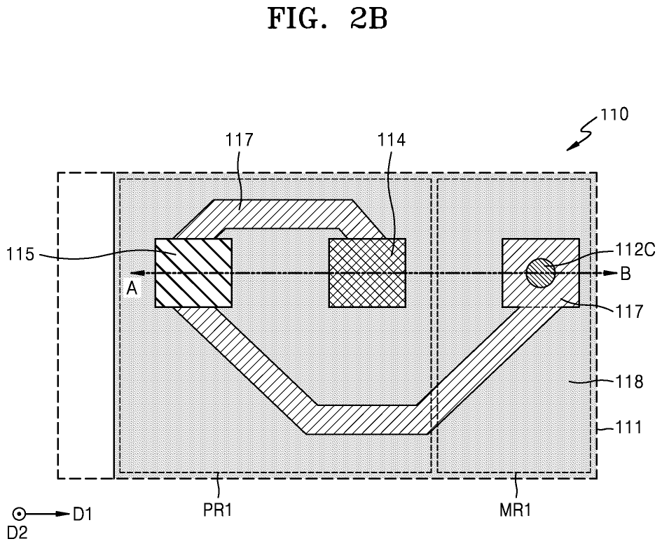

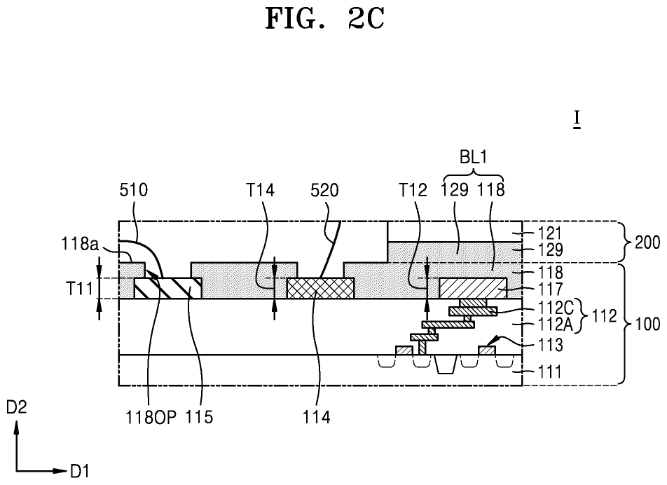

FIG. 2A is a cross-sectional view illustrating a semiconductor package according to embodiments. FIG. 2B is an enlarged plan view illustrating a portion of a first semiconductor chip according to embodiments. FIG. 2C is an enlarged cross-sectional view illustrating a region I of FIG. 2A and a cross-section taken along a line A-B of FIG. 2B. Hereinafter, the redundant description to those described above will be omitted.

Referring to FIGS. 2A to 2C, a semiconductor package 1A may include a substrate 300, a chip stack CS, first to fourth bonding wires 510, 520, 530, and 540, and a molding layer 400. The chip stack CS may include first to fourth semiconductor chips 110, 120, 130, and 140, which are stacked on one another. The substrate 300, the first to fourth semiconductor chips 110, 120, 130, and 140, the first to fourth bonding wires 510, 520, 530, and 540, and the molding layer 400 may be the same as or similar to those described in the examples of FIGS. 1A through 1E.

For example, the first chip pad 115 may be connected to the upper substrate pad 310 through the first bonding wire 510. However, the first semiconductor chip 110 may further include a first connection pad 114. The first connection pad 114 is provided on the first pad region PRI of the first semiconductor die 111 and may be exposed by the second semiconductor chip 120. The first connection pad 114 may be disposed between the first chip pad 115 and the second semiconductor chip 120 in a plan view. The first connection pad 114 is provided on the top surface of the first wiring layer 112 and may be laterally spaced apart from the first chip pad 115.

The second bonding wire 520 may be connected to the second chip pad 125 and the first connection pad 114. As shown in FIG. 2B, the first connection pad 114 may be electrically connected to the first chip pad 115 via a first redistribution pattern 117. Accordingly, the second semiconductor chip 120 may be electrically connected to the substrate 300 via the second bonding wire 520, the first connection pad 114, the first redistribution pattern 117, the first chip pad 115, and the first bonding wire 510. The planar arrangement of the first chip pad 115, the first redistribution pattern 117, and the first connection pad 114 in FIG. 2B is an example and may be modified in various forms.

As shown in FIG. 2C, the thickness T14 of the first connection pad 114 may be about 95% to about 105% of the thickness T11 of the first chip pad 115 and may be about 95% to about 105% of the thickness T12 of the first redistribution pattern 117. The first connection pad 114 may include the same metallic material as the first chip pad 115 and the first redistribution pattern 117. The first connection pad 114 may be formed in a single process with the first chip pad 115 and the first redistribution pattern 117.

As shown in FIG. 2A, the second semiconductor chip 120 may further include a second connection pad 124. The second connection pad 124 is provided on the top surface of the second wiring layer 122 and may be laterally spaced apart from the second chip pad 125. The second connection pad 124 may be disposed between the second chip pad 125 and the third semiconductor chip 130 in a plan view. The second connection pad 124 may be exposed by the third semiconductor chip 130.

The thickness of the second connection pad 124 may be about 95% to about 105% of the thickness of the second chip pad 125 and may be about 95% to about 105% of the thickness of the second redistribution pattern 127. The second connection pad 124 may include the same metal material as the second chip pad 125 and the second redistribution pattern 127. The second connection pad 124 may be formed by a single process with the second chip pad 125 and the second redistribution pattern 127.

The connections of the second connection pad 124, the second redistribution pattern 127, and the second chip pad 125 may be the same as or similar to those described in the example of the connections of the first connection pad 114, the first redistribution pattern 117, and the first chip pad 115 in FIG. 2B. For example, the second connection pad 124 may be electrically connected to the second chip pad 125 via the second redistribution pattern 127.

The third bonding wire 530 may be connected to the third chip pad 135 and the second connection pad 124. The third semiconductor chip 130 may be electrically connected to the second bonding wire 520 and the substrate 300 via the third bonding wire 530, the second connection pad 124, the second redistribution pattern 127, and the second chip pad 125.

The third semiconductor chip 130 may further include a third connection pad 134. The third connection pad 134 is provided on the top surface of the third wiring layer 132, and may be spaced laterally apart from the third chip pad 135. The third connection pad 134 may be exposed by the fourth semiconductor chip 140. The third connection pad 134 may be disposed between the third chip pad 135 and the fourth semiconductor chip 140 in a plan view. The thickness of the third connection pad 134 may be about 95% to about 105% of the thickness of the third chip pad 135 and may be about 95% to about 105% of the thickness of the third redistribution pattern 137. The third connection pad 134 may include the same metal material as the third chip pad 135 and the third redistribution pattern 137.

The connections of the third connection pad 134, the third redistribution pattern 137, and the third chip pad 135 may be the same as or similar to those described in the example of the connections of the first connection pad 114, the first redistribution pattern 117, and the first chip pad 115 in FIG. 2B. For example, the third connection pad 134 may be electrically connected to the third chip pad 135 via the third redistribution pattern 137.

The fourth bonding wire 540 may be connected to the fourth chip pad 145 and the third connection pad 134. Accordingly, the fourth chip pad 145 may be electrically connected to the third bonding wire 530 via the fourth bonding wire 540, the third connection pad 134, the third redistribution pattern 137, and the third chip pad 135.

The fourth semiconductor chip 140 may further include a fourth connection pad 144, but the embodiments are not limited thereto.

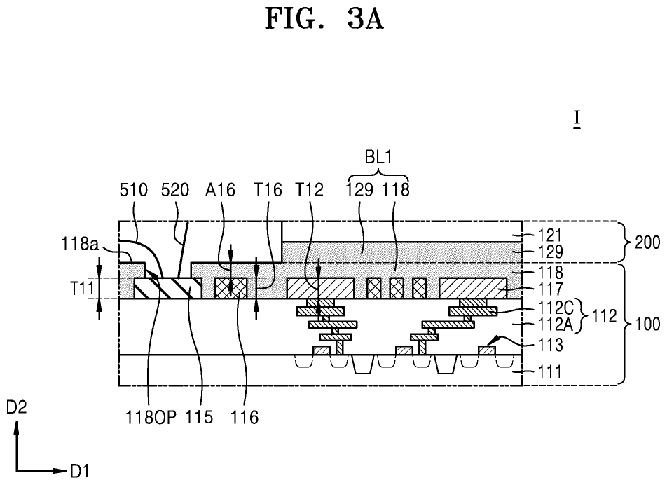

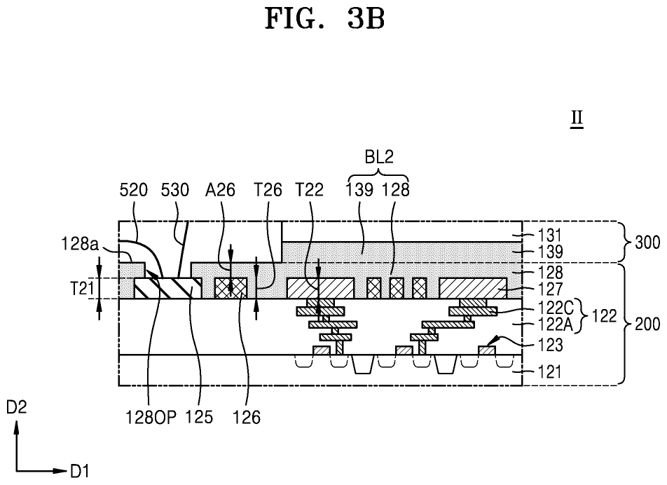

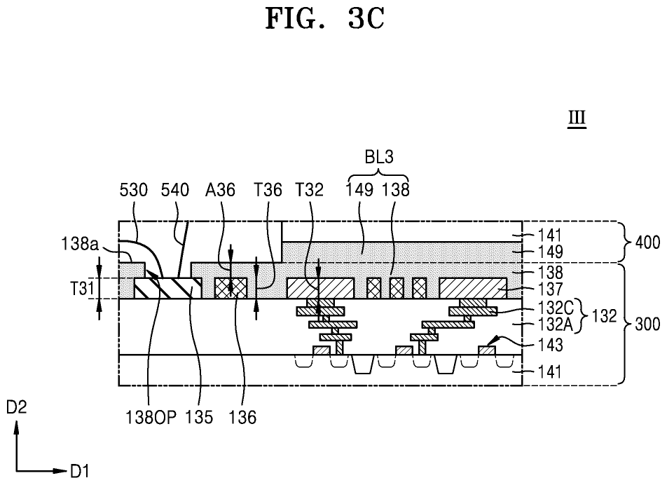

FIG. 3A is a cross-sectional view for explaining a first semiconductor chip according to embodiments, which corresponds to an enlarged view of the region I of FIG. 1A.

Referring to FIG. 3A, the first semiconductor chip 110 may further include a first dummy pattern 116. The first dummy pattern 116 is provided on the top surface of the first wiring layer 112, and may be laterally spaced apart from the plurality of first redistribution patterns 117 and the first chip pad 115. A plurality of first dummy patterns 116 may be provided, but are not limited thereto. The first dummy patterns 116 may be spaced apart from and the first wiring structures 112C, and may be electrically insulated from the first integrated circuits 113 and the first wiring structures 112C.

The first dummy patterns 116 may be provided between the first redistribution patterns 117 or between the first chip pad 115 and the first redistribution patterns 117. Since the first dummy patterns 116 are provided, undulation of the top surface 118a of the first upper insulating layer 118 may not occur or may be reduced. For example, in the process of forming the first upper insulating layer 118, the first dummy patterns 116 may buffer a step difference between the top surfaces of the first redistribution patterns 117 and the top surfaces of the first insulating layer 112A and a step difference between the top surface of the first chip pad 115 and the top surface of the first wiring layer 112. Accordingly, the top surface 118a of the first upper insulating layer 118 may be formed to be further flat. For example, a level difference between an uppermost portion and a lowermost portion of the top surface 118a of the first upper insulating layer 118 may be equal to or less than about 50 Å or less. Accordingly, direct bonding between the bottom surface of the second lower insulating layer 129 and the top surface 118a of the first upper insulating layer 118 may be formed with a better condition.

The thickness T16 of each of the first dummy patterns 116 may be about 95% to about 105% of the thickness T12 of each of the first redistribution patterns 117, and about 95% to about 105% of the thickness T11 of the first chip pad 115. The thickness T16 of each of the first dummy patterns 116 satisfies such a condition, and the top surface 118a of the first upper insulating layer 118 may be further flat.

The first dummy patterns 116 may include the same metal material as the first redistribution patterns 117 and the first chip pad 115. The first dummy patterns 116 may be formed by a single process with the first redistribution patterns 117 and the first chip pad 115.

A level difference A16 between the top surface 118a of the first upper insulating layer 118 and the top surface of the first redistribution pattern 117 may be about 0.1 μm to about 2 μm.

FIG. 3B is a cross-sectional view for explaining a second semiconductor chip according to embodiments, which corresponds to an enlarged view of the region II of FIG. 1A.

Referring to FIG. 3B, the second semiconductor chip 120 may further include a second dummy pattern 126. The second dummy pattern 126 is provided on the top surface of the second wiring layer 122 and may be laterally spaced apart from the plurality of second redistribution patterns 127 and the second chip pad 125. For example, a plurality of second dummy patterns 126 may be provided. The second dummy patterns 126 may be spaced apart from the second wiring structures 122C. The second dummy patterns 126 may be electrically insulated from the second integrated circuits 123 and the second wiring structures 122C.

The second dummy patterns 126 may be provided between the second redistribution patterns 127 or between the second chip pad 125 and the second redistribution patterns 127. Since the second dummy patterns 126 are provided, the undulation of the top surface 128a of the second upper insulating layer 128 may be alleviated, and the top surface 128a of the second upper insulating layer 128 may be formed to be more flat. Accordingly, bonding between the top surface 128a of the second upper insulating layer 128 and the bottom surface of the third lower insulating layer 139 may be formed with a good condition.

The thickness T26 of each of the second dummy patterns 126 may be about 95% to about 105% of the thickness T22 of each of the second redistribution patterns 127, and about 95% to about 105% of the thickness T21 of the second chip pad 125. The thickness T26 of each of the second dummy patterns 126 satisfies such a condition, and the top surface 128a of the second upper insulating layer 128 may be further flat. The second dummy patterns 126 may include the same material as the second redistribution patterns 127 and the second chip pad 125. The second dummy patterns 126 may be formed by a single process with the second redistribution patterns 127 and the second chip pad 125.

A level difference A26 between the top surface 128a of the second upper insulating layer 128 and the top surface of each of the second dummy patterns 126 may be about 0.1 μm to about 2 μm.

FIG. 3C is a cross-sectional view for explaining a third semiconductor chip according to embodiments, which corresponds to an enlarged view of the region III of FIG. 1A.

Referring to FIG. 3C, the third semiconductor chip 130 may further include a third dummy pattern 136. The third dummy pattern 136 is provided on the top surface of the third wiring layer 132 and may be laterally spaced apart from the plurality of third redistribution patterns 137 and the third chip pad 135. For example, a plurality of third dummy patterns 136 may be provided. The third dummy patterns 136 may be spaced apart from the third wiring structures 132C. The third dummy patterns 136 may be electrically insulated from the third integrated circuits 143 and the third wiring structures 132C.

The third dummy patterns 136 may be provided between the third redistribution patterns 137 or between the third chip pad 135 and the third redistribution patterns 137. Since the third dummy patterns 136 are provided, undulation of the top surface 138a of the third upper insulating layer 138 may not occur or may be reduced. The top surface 138a of the third upper insulating layer 138 may be further flat. Accordingly, bonding between the bottom surface of the fourth lower insulating layer 149 and the top surface 138a of the third upper insulating layer 138 may be formed with a good condition.

The thickness T36 of each of the third dummy patterns 136 may be about 95% to about 105% of the thickness T32 of each of the third redistribution patterns 137, and about 95% to about 105% of the thickness T31 of the third chip pad 135. The thickness T36 of each of the third dummy patterns 136 satisfies such a condition, and the top surface 138a of the third upper insulating layer 138 may be further flat. The third dummy patterns 136 may include the same material as the third redistribution patterns 137 and the third chip pad 135. The third dummy patterns 136 may be formed by a single process together with the third redistribution patterns 137 and the third chip pad 135.

A level difference A36 between the top surface 138a of the third upper insulating layer 138 and the top surface of each of the third dummy patterns 136 may be about 0.1 μm to about 2 μm.

Referring back to FIG. 1A, the fourth semiconductor chip 140 may further include a fourth dummy pattern (not shown). In this case, the fourth dummy pattern may be provided on the fourth wiring layer 142 and may be laterally spaced apart from the fourth chip pad 145. The fourth upper insulating layer 148 may cover the fourth wiring layer 142, the fourth dummy pattern, and the fourth chip pad 145.

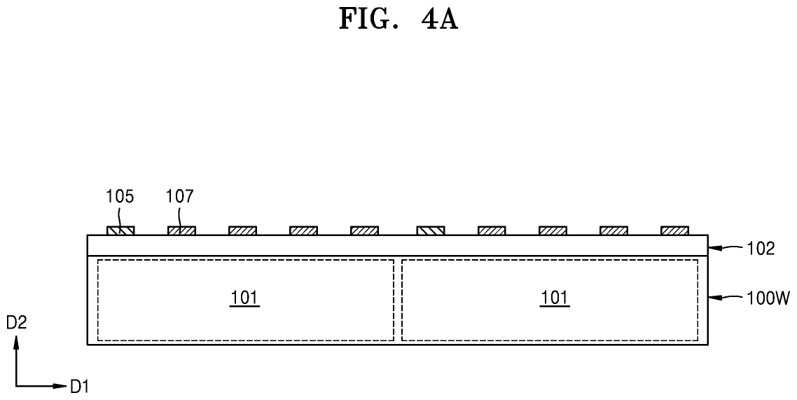

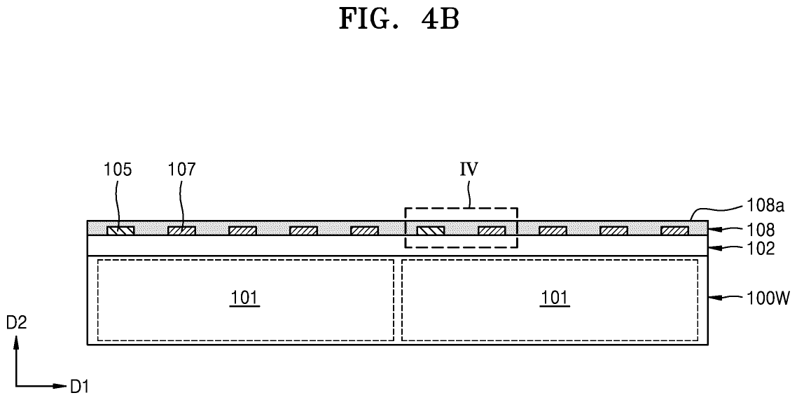

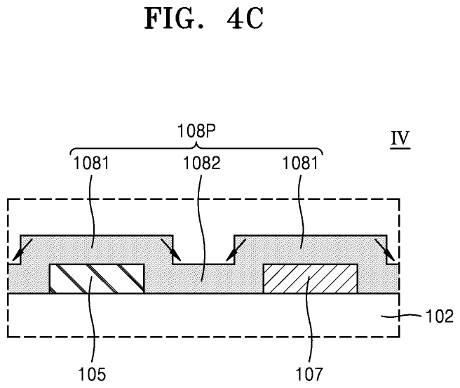

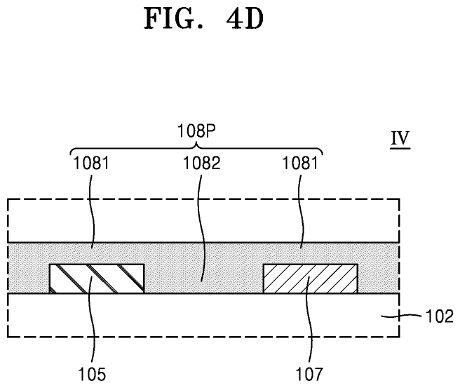

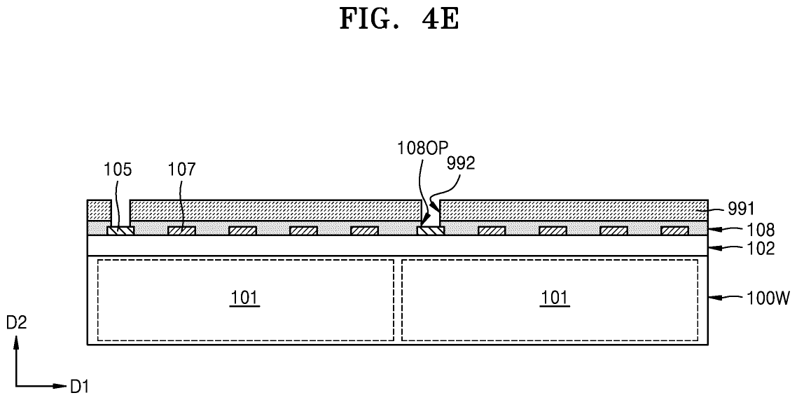

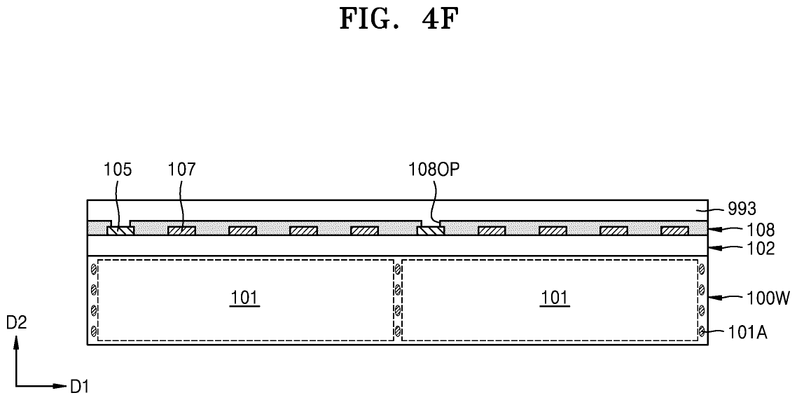

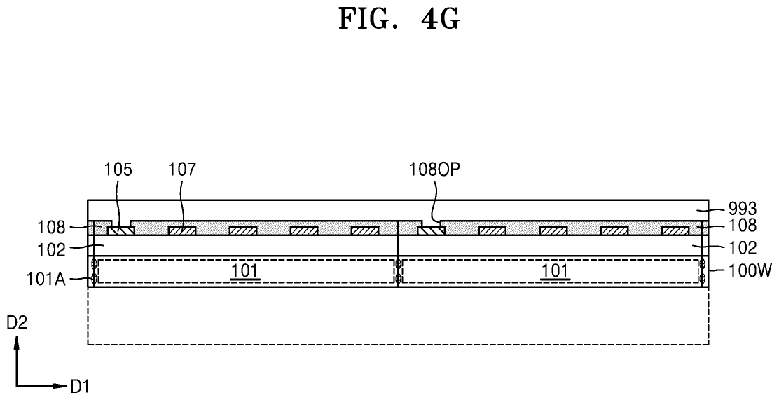

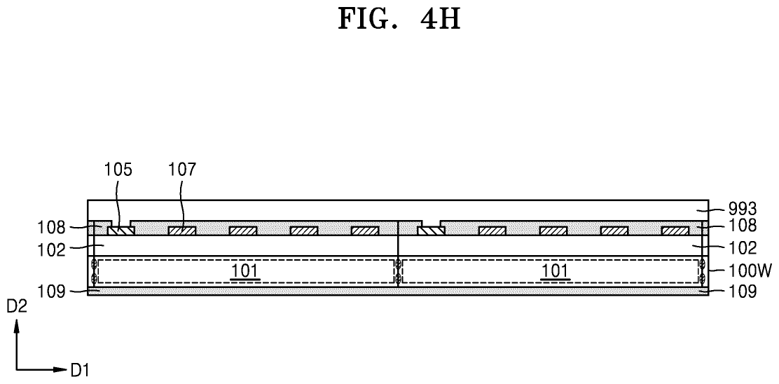

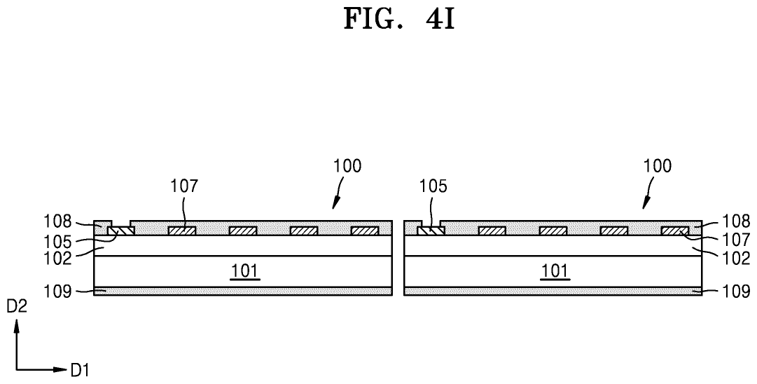

FIGS. 4A to 4I are cross-sectional views for explaining a fabrication process of a semiconductor chip according to embodiments. Hereinafter, the redundant description to those described above will be omitted.

Referring to FIG. 4A, a semiconductor wafer 100 W may be prepared. The semiconductor wafer 100 W may include a crystalline semiconductor material. The semiconductor wafer 100 W may include a plurality of semiconductor dies 101. The semiconductor dies 101 may be laterally disposed to each other, and may be connected to each other. The semiconductor dies 101 may be defined by scribe lanes (not shown) provided on one surface of the semiconductor wafer 100 W. The scribe lanes may be provided between the semiconductor dies 101 in a plan view. The integrated circuits and the wiring layers 102 may be formed on top surfaces of the semiconductor dies 101. The formation of the wiring layer 102 may be performed at a wafer level. A portion of the wiring layer 102 may be substantially the same as the first wiring layer 112 of FIG. 1C, the second wiring layer 122 of FIG. 1D, and the third wiring layer 132 of FIG. 1E. For example, although not shown, the wiring layer 102 may include insulating layers and wiring structures. A portion of the wiring layer 102 may be disposed on any one of the semiconductor dies 101.

The chip pad 105 and the redistribution pattern 107 may be formed on the wiring layer 102. Forming the chip pad 105 and the redistribution pattern 107 may include forming a conductive layer on the wiring layer 102 and patterning the conductive layer. Accordingly, the redistribution pattern 107 includes the same material as the chip pad 105, and may have a thickness of about 95% to about 105% of the chip pad 105. A plurality of redistribution patterns 107 may be formed.

Referring to FIG. 4B, an upper insulating layer 108 may be formed on the wiring layer 102 to cover the chip pad 105 and the redistribution pattern 107. The upper insulating layer 108 may be formed at a wafer level. For example, forming the upper insulating layer 108 may include coating a preparation solution on the chip pad 105 and the redistribution pattern 107 to form a preliminary insulating layer 108P (FIG. 4C) and curing the preliminary insulating layer 108P. As another example, the upper insulating layer 108 may be formed by a deposition process such as chemical vapor deposition (CVD). Hereinafter, the formation of the preliminary insulating layer 108P by the coating process and the formation of the upper insulating layer 108 by the curing process will be described in more detail.

FIG. 4C is a view for explaining the preliminary insulating layer immediately after coating, and corresponds to an enlarged view of a region IV of FIG. 4B. FIG. 4D is a view for explaining the preliminary insulating layer when time elapses after a coating process, and corresponds to an enlarged view showing a region IV of FIG. 4B.

Referring to FIG. 4C, the preliminary insulating layer 108P may include a first portion 1081 and a second portion 1082. That is, the preliminary insulating layer 108P may have a flat top surface. The first portion 1081 of the preliminary insulating layer 108P may be provided on the chip pad 105 and the redistribution pattern 107. The second portion 1082 of the preliminary insulating layer 108P is provided on the top surface of the upper insulating layer 108, and may be spaced apart from the chip pad 105 and the redistribution pattern 107 from a plan view. The top surface of the preliminary insulating layer 108P immediately after the coating may have an undulation. For example, the top surface of the first portion 1081 of the preliminary insulating layer 108P may be provided at a higher level than the top surface of the second portion 1082. Since the preliminary insulating layer 108P is in a liquid state, the preliminary insulating layer 108P may have fluidity. Accordingly, the first portion 1081 of the preliminary insulating layer 108P may move, as indicated by an arrow, toward the second portion 1082.

As shown in FIG. 4D, as time elapses after the coating process, the top surface of the first portion 1081 of the preliminary insulating layer 108P may be provided at the same or similar level as the top surface of the second portion 1082. Thereafter, the curing process of the preliminary insulating layer 108P may be performed to form the upper insulating layer 108 of FIG. 4B. For example, the curing process of the preliminary insulating layer 108P may include a thermosetting process.

Referring back to FIG. 4B, the top surface 108a of the upper insulating layer 108 may be substantially flat. For example, a level difference between an uppermost portion and a lowermost portion of the top surface 138a of the third upper insulating layer 138 may be about 50 Å or less.

A planarization process may be further performed on the top surface 108a of the upper insulating layer 108. The planarization process may include a chemical mechanical polishing process. The top surface 108a of the upper insulating layer 108 may be further flattened by the planarization process. The upper insulating layer 108 may have a thickness of about 1 μm to about 10 μm.

Referring to FIG. 4E, a photoresist layer 991 may be formed on the upper insulating layer 108. The photoresist layer 991 may have a guide opening 992. The guide opening 992 of the photoresist layer 991 may expose the upper insulating layer 108. The guide opening 992 of the photoresist layer 991 may be vertically spaced apart from the top surface of the chip pad 105.

The upper insulating layer 108 exposed by the photoresist layer 991 may be etched to form a pad opening 1080P. The pad opening 1080P may expose the chip pad 105. Thereafter, the photoresist layer 991 may be removed so that the top surface of the upper insulating layer 108 may be exposed.

Referring to FIG. 4F, a temporary tape 993 may be formed on the top surface of the exposed upper insulating layer 108 to cover the upper insulating layer 108 and the chip pad 105. For example, forming the temporary tape 993 may be performed by a lamination process.

The laser is irradiated into the semiconductor wafer 100 W, so that the semiconductor wafer 100 W may be locally heated. The crystal structure of the heated region of the semiconductor wafer 100 W may be deformed to form amorphous portions 101A in the semiconductor wafer 100 W. The laser is irradiated along the scribe lane region of the semiconductor wafer 100 W, and the amorphous portions 101A may overlap the scribe lane region in a plan view. The amorphous portions 101A may be formed in the semiconductor wafer 100 W at different depths. For example, the amorphous portions 101A may be provided at different depths from the bottom surface of the semiconductor wafer 100 W.

Referring to FIG. 4G, a grinding process is performed on the bottom surface of the semiconductor wafer 100 W such that a portion of the semiconductor wafer 100 W may be removed as indicated by the dashed lines. For example, the grinding process may be performed on the bottom surfaces of the semiconductor dies 101, thereby thinning the semiconductor dies 101. The grinding process may include a back lap process or a chemical mechanical polishing process. The ground bottom surfaces of the semiconductor dies 101 may be substantially flat.

In the grinding process of the semiconductor dies 101, the amorphous portions 101A may act as crack seeds. For example, cracks may be formed from the amorphous portions 101A of the semiconductor wafer 100 W. Cracks may be propagated vertically from the amorphous portions 101A toward the bottom surface of the semiconductor wafer 100 W and the top surface of the wiring layer 102. Propagation of the crack may cause the semiconductor wafer 100 W, the wiring layer 102, and the upper insulating layer 108 to be diced. The wiring layer 102 and the upper insulating layer 108 may be diced to form the plurality of wiring layers 102 and the plurality of upper insulating layers 108. The plurality of wiring layers 102 may be disposed on the corresponding semiconductor dies 101, respectively. A plurality of upper insulating layers 108 may be disposed on the corresponding semiconductor dies 101, respectively.

Referring to FIG. 4H, a lower insulating layer 109 may be formed on the ground bottom surfaces of the semiconductor dies 101 to cover the bottom surfaces of the semiconductor dies 101. The lower insulating layer 109 may be formed at a wafer level. For example, forming the lower insulating layer 109 may include coating a preparation solution on the bottom surfaces of the semiconductor dies 101 to form a preliminary lower insulating layer and curing the preliminary lower insulating layer. The coating and curing are the same as described in the example of the formation of the upper insulating layer 108 of FIGS. 4B to 4D. As another example, the preliminary insulating layer may be formed by a deposition process such as chemical vapor deposition (CVD). The lower insulating layer 109 may include an inorganic insulating material and/or an organic insulating material. The lower insulating layer 109 may include, for example, the same material as the upper insulating layer 108. The lower insulating layer 109 may have a thickness of about 1 μm to about 10 μm.

No other components may be provided between the lower insulating layer 109 and each of the semiconductor dies 101. For example, the lower insulating layer 109 may be in direct physical contact with the bottom surfaces of the semiconductor dies 101. Accordingly, the lower insulating layer 109 may be formed to have a relatively small thickness. For example, the thickness of the lower insulating layer 109 may be less than the thickness of the upper insulating layer 108.

Referring to FIG. 4I, the semiconductor dies 101 may be laterally spaced apart from each other. Since the semiconductor dies 101 are spaced apart from each other, the wiring layers 102 and the upper insulating layers 108 on the semiconductor dies 101 may be laterally spaced apart and separated from each other. While the semiconductor dies 101 are laterally spaced apart from each other, the lower insulating layer 109 may be cut to form a plurality of separated lower insulating layers 109. The lower insulating layers 109 may be disposed on bottom surfaces of the corresponding semiconductor dies 101, respectively. Accordingly, the fabrication of the semiconductor chips 100 may be completed. Each of the semiconductor chips 100 may include any one of the semiconductor dies 101, a corresponding wiring layer 102, a corresponding upper insulating layer 108, a corresponding lower insulating layer 109, a corresponding chip pad 105, and corresponding redistribution patterns 107.

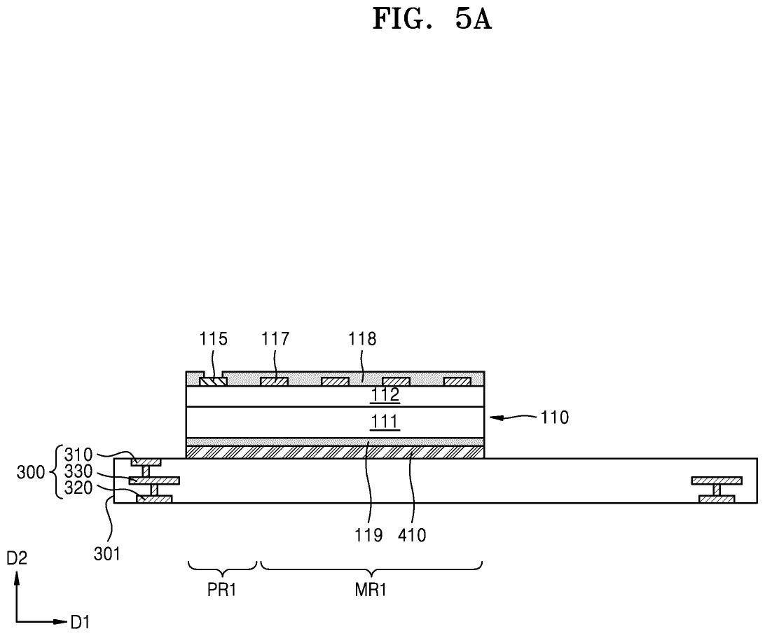

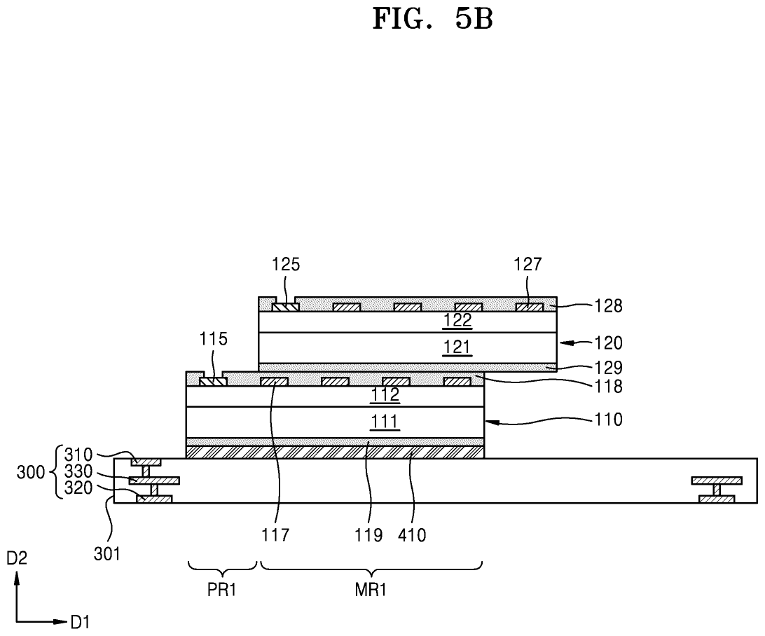

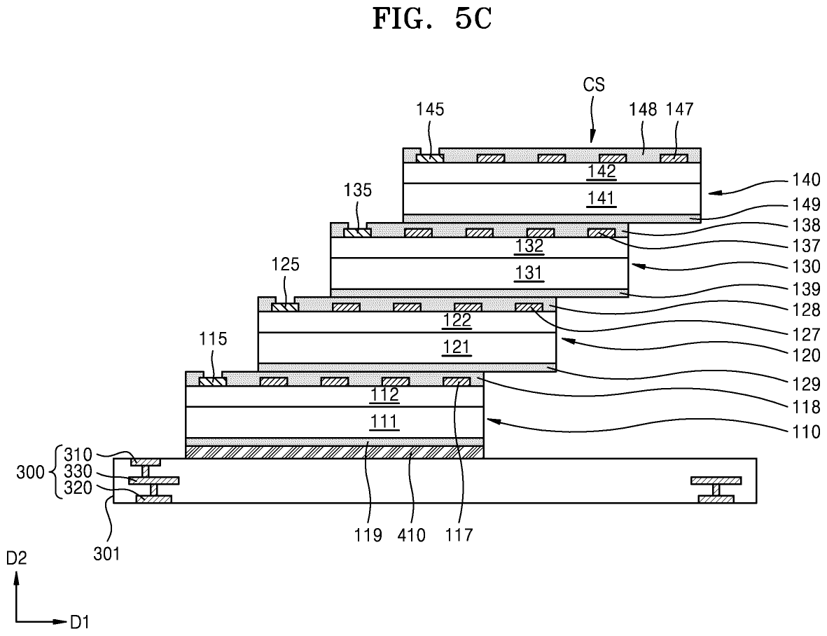

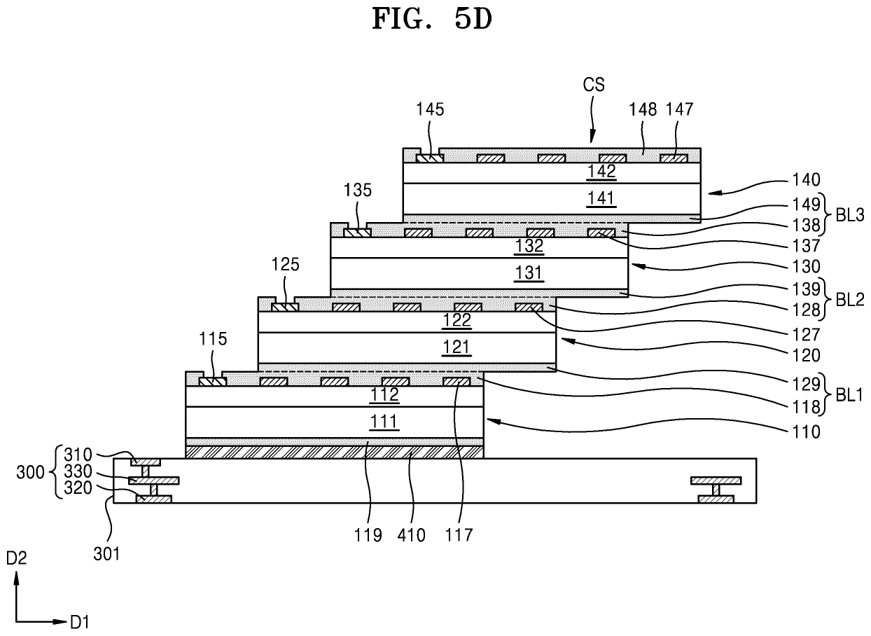

FIGS. 5A to 5D are cross-sectional views for explaining a fabrication process of a semiconductor package according to embodiments. Hereinafter, the redundant description to those described above will be omitted.

Referring to FIG. 5A, a first semiconductor chip 110 may be disposed on a substrate 300. The first semiconductor chip 110 may be manufactured as in the previous examples of FIGS. 4A to 4I. The first semiconductor chip 110 may be substantially the same as any one of the semiconductor chips 100 of FIG. 4I. For example, the first semiconductor die 111, the first lower insulating layer 119, the first wiring layer 112, the first chip pad 115, the first redistribution patterns 117, and the first upper insulating layer 118 may be substantially the same as any one of the semiconductor dies 101, any one of the lower insulating layers 109, any one of the wiring layers 102, any one of the chip pad 105, any one of the redistribution patterns 107, and any one of the upper insulating layers 108 of FIG. 4I. An adhesive layer 410 may be provided between the first semiconductor chip 110 and the substrate 300 so that the first semiconductor chip 110 may be attached to the substrate 300.

Referring to FIG. 5B, a second semiconductor chip 120 may be disposed on the first semiconductor chip 110. Any one of the semiconductor chips 100 fabricated as in the examples of FIGS. 4A to 4I may be used as the second semiconductor chip 120. The second semiconductor chip 120 may vertically overlap the first mounting region MR1 of the first semiconductor die 111 and may be spaced apart from the first pad region PRI of the first semiconductor die 111. In this case, an adhesive layer such as a die attach film may not be provided between the first semiconductor chip 110 and the second semiconductor chip 120. Arranging the second semiconductor chip 120 may include physically contacting a second portion of the second lower insulating layer 129 with the first upper insulating layer 118. The first portion of the second lower insulating layer 129 may be spaced apart from the first upper insulating layer 118.

A first bonding process may be performed on the first semiconductor chip 110 and the second semiconductor chip 120. Performing the first bonding process may include applying a pressure of about 3 N/cm² to about 100 N/cm² on the first semiconductor chip 110 and the second semiconductor chip 120. The first upper insulating layer 118 and the second lower insulating layer 129 may be primarily bonded by the first bonding process. For example, the second portion of the second lower insulating layer 129 may be physically bonded to the first upper insulating layer 118. The first bonding process may be a temporary bonding process, but is not limited thereto.

Referring to FIG. 5C, a third semiconductor chip 130 may be disposed on the second semiconductor chip 120. Any one of the semiconductor chips 100 fabricated as in the examples of FIGS. 4A to 4I may be used as the third semiconductor chip 130. The third semiconductor chip 130 may be shifted from the second semiconductor chip 120 in the first direction D1 to expose the second chip pad 125. In this case, an adhesive layer such as a die attach film may not be provided between the second semiconductor chip 120 and the third semiconductor chip 130.

A second bonding process may be performed on the second semiconductor chip 120 and the third semiconductor chip 130. Performing the second bonding process may include applying a pressure of about 3 N/cm² to about 100 N/cm² on the second semiconductor chip 120 and the third semiconductor chip 130. The second upper insulating layer 128 and the third lower insulating layer 139 may be primarily bonded by the second bonding process. The bonding between the second upper insulating layer 128 and the third lower insulating layer 139 may be a temporary bonding, but is not limited thereto.

A fourth semiconductor chip 140 may be disposed on the third semiconductor chip 130. The fourth semiconductor chip 140 may be manufactured as in the examples of FIGS. 4A to 4I. The fourth semiconductor chip 140 may be spaced apart from the third chip pad 135. An adhesive layer such as a die attach film may not be provided between the third semiconductor chip 130 and the fourth semiconductor chip 140.

A third bonding process may be performed on the third semiconductor chip 130 and the fourth semiconductor chip 140. Performing the third bonding process may include applying a pressure of about 3 N/cm² to about 100 N/cm² on the third semiconductor chip 130 and the fourth semiconductor chip 140. The third upper insulating layer 138 and the fourth lower insulating layer 149 may be primarily bonded by the third bonding process. The bonding between the third upper insulating layer 138 and the fourth lower insulating layer 149 may be a temporary bonding.

According to embodiments, each of the first to fourth semiconductor chips 110, 120, 130, and 140 may be any one of the semiconductor chips 100 of FIG. 4I. In this case, the thickness of the first upper insulating layer 118 may be substantially the same as the thickness of the second upper insulating layer 128, the thickness of the third upper insulating layer 138, and the thickness of the fourth upper insulating layer 148. The material of the first upper insulating layer 118 may be substantially the same as the material of the second upper insulating layer 128, the material of the third upper insulating layer 138, and the material of the fourth upper insulating layer 148. The thickness of the second lower insulating layer 129 may be substantially the same as the thickness of the third lower insulating layer 139 and the thickness of the fourth lower insulating layer 149. The material of the second lower insulating layer 129 may be substantially the same as the material of the first lower insulating layer 119, the material of the third lower insulating layer 139, and the material of the fourth lower insulating layer 149.

Referring to FIG. 5D, an annealing process may be performed on the first semiconductor chip 110, the second semiconductor chip 120, the third semiconductor chip 130, and the fourth semiconductor chip 140. The annealing process may be performed under a temperature condition of about 100° C. to about 200° C. The annealing process may be performed for about 10 minutes to about 120 minutes. A chemical bond may be formed between the first upper insulating layer 118 and the second lower insulating layer 129 by the annealing process, and the second lower insulating layer 129 may be connected to the first upper insulating layer 118 without a boundary surface. Accordingly, the first bonding insulating layer BL1 may be formed. The first bonding insulating layer BL1 may include the first upper insulating layer 118 and the second lower insulating layer 129, which are directly bonded to each other.

Likewise, a chemical bond may be formed between the second upper insulating layer 128 and the third lower insulating layer 139. The third lower insulating layer 139 may be connected to the second upper insulating layer 128 without a boundary surface, thereby forming a second bonding insulating layer BL2. The second bonding insulating layer BL2 may include the second upper insulating layer 128 and the third lower insulating layer 139, which are directly bonded to each other.

A chemical bond may be formed between the third upper insulating layer 138 and the fourth lower insulating layer 149. The fourth lower insulating layer 149 may be connected to the third upper insulating layer 138 without a boundary surface. Accordingly, a third bonding insulating layer BL3 may be formed. The third bonding insulating layer may include the third upper insulating layer 138 and the fourth lower insulating layer 149, which are directly bonded to each other.

Manufacturing of the chip stack CS may be completed by the examples described so far. The chip stack CS may include first to fourth semiconductor chips 110, 120, 130, and 140, and two adjacent chips among the first to fourth semiconductor chips 110, 120, 130, and 140 may be directly bonded to each other.

Referring back to FIG. 1A, the first bonding wire 510, the second bonding wire 520, the third bonding wire 530, and the fourth bonding wire 540 may be formed. The first bonding wire 510, the second bonding wire 520, the third bonding wire 530, and the fourth bonding wire 540 may be formed on the first semiconductor chip 110, the second semiconductor chip 120, the third semiconductor chip 130, and the fourth semiconductor chip 140, respectively. Alternatively, the first through fourth bonding wires 510, 520, 530, and 540 may be formed as described in the examples of FIGS. 2A to 2C. The molding layer 400 may be formed on the substrate 300 to cover the first to fourth semiconductor chips 110, 120, 130, and 140 and the first to fourth bonding wires 510, 520, 530, and 540. Solder balls 350 may be formed on the bottom surface of the substrate 300. Accordingly, manufacturing of the semiconductor package 1 may be completed.

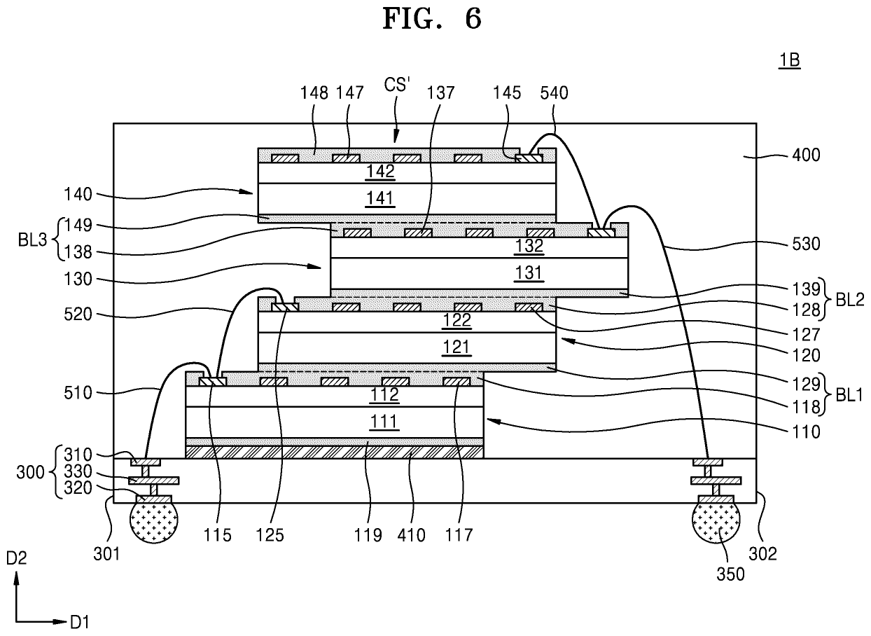

FIG. 6 is a cross-sectional view illustrating a semiconductor package according to embodiments.

Referring to FIG. 6, a semiconductor package 1B may include a substrate 300, a chip stack (CS′), first to fourth bonding wires 510, 520, 530, and 540, and a molding layer 400. The chip stack CS' may include first to fourth semiconductor chips 110, 120, 130, and 140, which are stacked on one another. The substrate 300, the first to fourth semiconductor chips 110, 120, 130, and 140, the first to fourth bonding wires 510, 520, 530, and 540, and the molding layer 400 may be the same as or similar to those described in the examples of FIGS. 1A through IE. For example, the second semiconductor chip 120 may be arranged shifted in the first direction D1 from the first semiconductor chip 110. The third semiconductor chip 130 may be arranged shifted in the first direction D1 from the second semiconductor chip 120.

However, the third chip pad 135 may be disposed between the second side surface 302 of the substrate 300 and the third redistribution pattern 137 in a plan view. The second side surface 302 of the substrate 300 may face the first side surface 301 of the substrate 300.

The third bonding wire 530 may be connected to the third chip pad 135 and the upper substrate pad 310. The third bonding wire 530 may be spaced apart from the second semiconductor chip 120. Accordingly, the third semiconductor chip 130 may be connected to the substrate 300 through the third bonding wire 530 without passing through the first chip pad 115 and the second chip pad 125.

The fourth semiconductor chip 140 may be shifted from the third semiconductor chip 130 in a direction opposite to the first direction D1. The fourth chip pad 145 may be disposed between the second side 302 of the substrate 300 and the fourth redistribution pattern 147 in a plan view.

The fourth bonding wire 540 may be connected to the third chip pad 135 and the fourth chip pad 145. The fourth semiconductor chip 140 may be connected to the substrate 300 through the fourth bonding wire 540, the third chip pad 135, and the third bonding wire 530.

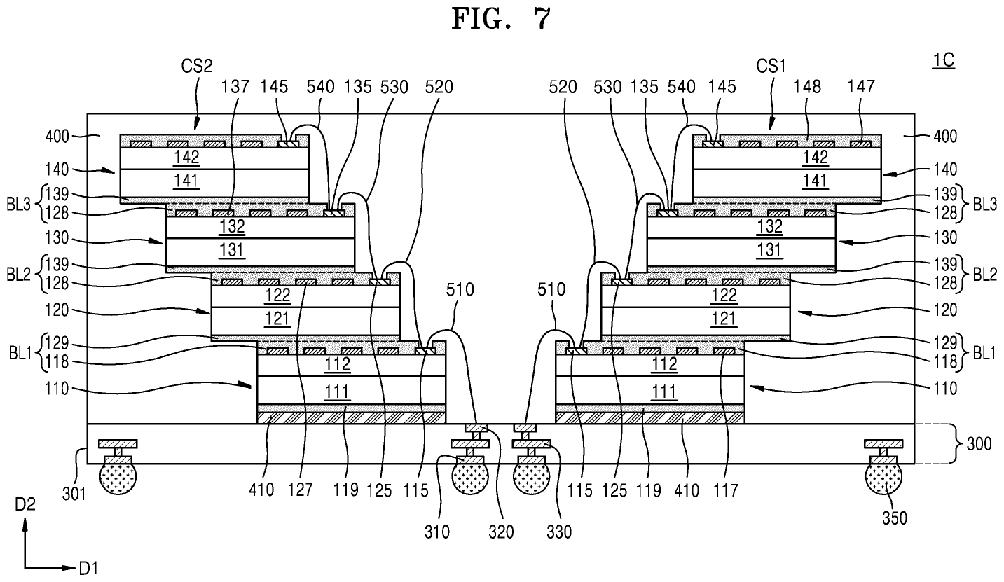

FIG. 7 is a cross-sectional view illustrating a semiconductor package according to embodiments.

Referring to FIG. 7, a semiconductor package 1C may include a substrate 300, solder balls 350, a first chip stack CS1, a second chip stack CS2, and a molding layer 400. The semiconductor package 1C may further include an adhesive layer 410. The second chip stack CS2 may be disposed between the first side surface 301 of the substrate 300 and the second chip stack CS2. The second chip stack CS2 may be spaced apart from the first chip stack CS1 in a direction opposite to the first direction D1.

Each of the first chip stack CS1 and the second chip stack CS2 may include first to fourth semiconductor chips 110, 120, 130, and 140, which are stacked on one another. The first to fourth semiconductor chips 110, 120, 130, and 140 may be substantially the same as those described in the examples of FIGS. 1A to IE. The first chip stack CS1 may have a stepwise stacked structure (i.e., a staircase structure) that moves up along the first direction D1.

The second chip stack CS2 may have a stepwise stacked structure (i.e., a staircase structure) that moves down along the first direction D1. For example, in the second chip stack CS2, the second semiconductor chip 120 may be shifted from the first semiconductor chip 110 in a direction opposite to the first direction D1. In the second chip stack CS2, the third semiconductor chip 130 may be shifted from the second semiconductor chip 120 in a direction opposite to the first direction D1. In the second chip stack CS2, the fourth semiconductor chip 140 may be shifted from the third semiconductor chip 130 in a direction opposite to the first direction D1. In the second chip stack CS2, the first to fourth chip pads 115, 125, 135, and 145 may be disposed adjacent to the first chip stack CS1 in a plan view. For example, the first chip pad 115 may be disposed between the first redistribution pads 117 and the first chip stack CS1 in a plan view. The second chip pad 125 may be disposed between the second redistribution pads 127 and the first chip stack CS1 in a plan view. The third chip pad 135 may be disposed between the third redistribution pads 137 and the first chip stack CS1 in a plan view. The fourth chip pad 145 may be disposed between the fourth redistribution pads 147 and the first chip stack CS1 in a plan view.

The substrate 300 may include a plurality of upper substrate pads 310. The upper substrate pads 310 may be disposed between the first semiconductor chip 110 of the first chip stack CS1 and the second semiconductor chip 120 of the second chip stack CS2 in a plan view. The electrical connection relationship among the substrate 300, the first to fourth semiconductor chips 110, 120, 130 and 140, and the first to fourth bonding wires 510, 520, 530, and 540 may be substantially the same as described in FIG. 1A. For example, the first bonding wires 510 may be provided on the first semiconductor chip 110 of the first chip stack CS1 and the first semiconductor chip 110 of the second chip stack CS2. The first semiconductor chip 110 of the first chip stack CS1 and the first semiconductor chip 110 of the second chip stack CS2 may be connected to the upper substrate pad 310 through the first bonding wires 510. Each of the second semiconductor chip 120 of the first chip stack CS1 and the second semiconductor chip 120 of the second chip stack CS2 may be connected to the first semiconductor chip 110 through the second bonding wires 520. Each of the third semiconductor chip 130 of the first chip stack CS1 and the third semiconductor chip 130 of the second chip stack CS2 may be connected to the second semiconductor chip 120 through the third bonding wires 530. Each of the fourth semiconductor chip of the first chip stack CS1 and the fourth semiconductor chip 140 of the second chip stack CS2 may be connected to the third semiconductor chip 130 through the fourth bonding wires 540. Otherwise, the electrical connection relationship among the substrate 300, the first to fourth semiconductor chips 110, 120, 130 and 140, and the first to fourth bonding wires 510, 520, 530, and 540 may be substantially the same as described in FIGS. 2A to 2C. As another example, at least one of the first chip stack CS1 and the second chip stack CS2 may be substantially the same as the chip stack CS' of FIG. 6.

The molding layer 400 may cover the first chip stack CS1 and the second chip stack CS2 on the substrate 300.

According to embodiments, the stacked semiconductor chips may be directly bonded. Accordingly, the height of the semiconductor package may be reduced. The semiconductor package may be miniaturized.

While the inventive concept has been particularly shown and described with reference to embodiments thereof, it will be understood that various changes in form and details may be made therein without departing from the scope of the following claims.

What is claimed is:

1. A semiconductor package comprising:
a substrate;
a first semiconductor chip on the substrate and comprising a first chip pad and a first upper insulating layer on sidewalls of the first chip pad;
a first bonding wire connected to a top surface of the first chip pad; and
a second semiconductor chip on a top surface of the first semiconductor chip and spaced apart from the first chip pad, wherein
the second semiconductor chip comprises a second semiconductor die and a second lower insulating layer on a bottom surface of the second semiconductor die, wherein
the second lower insulating layer is directly bonded to the first upper insulating layer by a chemical bond between the first upper insulating layer and the second lower insulating layer.

2. The semiconductor package of claim 1, wherein the second lower insulating layer and the first upper insulating layer are bonded to each other without a boundary surface therebetween.

3. The semiconductor package of claim 1, wherein
the second lower insulating layer is in physical contact with the bottom surface of the second semiconductor die, and
the first upper insulating layer comprises a pad opening that exposes the top surface of the first chip pad.

4. The semiconductor package of claim 1, wherein the first upper insulating layer and the second lower insulating layer comprise a silicon-containing material.

5. The semiconductor package of claim 1, wherein a thickness of the first upper insulating layer is greater than a thickness of the second lower insulating layer.

6. The semiconductor package of claim 1, wherein
the first semiconductor chip further comprises a first redistribution pattern on one side of the first chip pad, and
the first upper insulating layer is on a top surface and a sidewall of the first redistribution pattern.

7. The semiconductor package of claim 6, wherein the first semiconductor chip further comprises:
first integrated circuits; and
a first wiring layer comprising a first insulating layer and a first conductive structure, wherein
the first conductive structure is electrically connected to the first integrated circuits,
the first redistribution pattern is on a top surface of the first wiring layer and electrically connected to the first conductive structure, and
the first chip pad is electrically connected to the first conductive structure through the first redistribution pattern.

8. The semiconductor package of claim 7, wherein the first semiconductor chip further comprises:
a first dummy pattern on the top surface of the first wiring layer and laterally spaced apart from the first chip pad and the first redistribution pattern,
wherein the first dummy pattern is configured to reduce undulation of a top surface of the first upper insulating layer, and
wherein the first dummy pattern is insulated from the first integrated circuits.

9. The semiconductor package of claim 1, wherein a level difference between an uppermost portion and a lowermost portion of the first upper insulating layer is about 50 Å or less.

10. The semiconductor package of claim 1, wherein the second lower insulating layer comprises the same material as the first upper insulating layer.

11. A semiconductor package comprising:
a substrate;
a first semiconductor die on the substrate and comprising a first pad region and a first mounting region;
a first chip pad on a top surface of the first pad region of the first semiconductor die;
a second semiconductor die on the first mounting region of the first semiconductor die and laterally spaced apart from the first chip pad; and
a first bonding insulating layer between the first and second semiconductor dies, wherein
the first bonding insulating layer comprises a first upper insulating layer on a top surface of the first semiconductor die and a second lower insulating layer on a bottom surface of the second semiconductor die, wherein
the second lower insulating layer is directly bonded to the first upper insulating layer without an interface therebetween.

12. The semiconductor package of claim 11, wherein the first upper insulating layer and the second lower insulating layer are directly bonded by a chemical bond.

13. The semiconductor package of claim 11, wherein
the second semiconductor die has a portion that protrudes outward from the first semiconductor die so as to overhang the first semiconductor die,
the second lower insulating layer is between the first semiconductor die and the second semiconductor die and extends onto a bottom surface of the portion that protrudes outward from the first semiconductor die, and
the first upper insulating layer is on the first pad region and the first mounting region of the first semiconductor die and is on a sidewall of the first chip pad.

14. The semiconductor package of claim 11, further comprising:
a second chip pad on a top surface of the second semiconductor die;
a third semiconductor die on the second semiconductor die and laterally spaced apart from the second chip pad; and
a second bonding insulating layer between the second and third semiconductor dies, wherein the second bonding insulating layer comprises:
a second upper insulating layer on a top surface of the second semiconductor die and on a sidewall of the second chip pad; and
a third lower insulating layer on a bottom surface of the third semiconductor die, wherein the third lower insulating layer is directly bonded to the second lower insulating layer without an interface therebetween.

15. The semiconductor package of claim 14, further comprising:
a first bonding wire connected to a top surface of the first chip pad; and
a second bonding wire connected to a top surface of the second chip pad and to the first chip pad.

16. A semiconductor package comprising:
a substrate;
solder balls on a bottom surface of the substrate;
a first semiconductor chip on a top surface of the substrate and comprising a first semiconductor die, first integrated circuits, a first wiring layer, a first redistribution pattern, a first chip pad, and a first upper insulating layer;
a second semiconductor chip on the first semiconductor chip and laterally spaced apart from the first chip pad, wherein the second semiconductor chip comprises a second semiconductor die, second integrated circuits, a second wiring layer, a second redistribution pattern, a second chip pad, a second lower insulating layer, and a second upper insulating layer;
a first bonding wire connected to the first chip pad;
a second bonding wire connected to the second chip pad; and
a molding layer on the substrate and surrounding the first semiconductor chip, the second semiconductor chip, the first bonding wire, and the second bonding wire, wherein the first semiconductor die comprises a mounting region and a pad region,
the first chip pad is in the pad region of the first semiconductor die and laterally spaced apart from the mounting region,
the second semiconductor chip is in the mounting region of the first semiconductor die and laterally spaced apart from the pad region,
the first upper insulating layer is on a top surface of the mounting region and the pad region of the first semiconductor die, and is on side walls of the first chip pad,
a top surface of the first upper insulating layer is at a higher level than a top surface of the first chip pad and a top surface of the first redistribution pattern, and
the second lower insulating layer is directly bonded to the first upper insulating layer.

17. The semiconductor package of claim 16, wherein the second lower insulating layer and the first upper insulating layer are connected to each other without an interface therebetween.

18. The semiconductor package of claim 16, wherein
a level difference between the top surface of the first upper insulating layer and the top surface of the first redistribution pattern is about 0.1 μm to about 2 μm, and
a level difference between the top surface of the first upper insulating layer and the top surface of the first chip pad is about 0.1 μm to about 2 μm.

19. The semiconductor package of claim 16, wherein the first semiconductor chip further comprises:
a first dummy pattern on a top surface of the first wiring layer and laterally spaced apart from the first chip pad and the first redistribution pattern,
the first dummy pattern is insulated from the first integrated circuits,
a thickness of the first dummy pattern is about 95% to about 105% of a thickness of the first chip pad, and
the thickness of the first dummy pattern is about 95% to about 105% of a thickness of the first redistribution pattern.

20. The semiconductor package of claim 16, wherein
the first upper insulating layer comprises silicon oxide,
the second lower insulating layer comprises silicon oxide, and
the second lower insulating layer is directly bonded to the first upper insulating layer by oxide-to-oxide bonding.
